(19) United States
(12) Patent Application Publication
(10) Pub. No.: US 2014/0041805 A1
(43) Pub. Date: Feb. 13, 2014

(54) SUBSTRATE PROCESSING APPARATUS AND GAS SUPPLY APPARATUS

(71) Applicant: TOKYO ELECTRON LIMITED, Tokyo (JP)

(72) Inventors: Yasuhiro KUGA, Kumamoto (JP); Masashi ITONAGA, Kumamoto (JP)

(73) Assignee: TOKYO ELECTRON LIMITED, Tokyo (JP)

(21) Appl. No.: 13/958,837

(22) Filed: Aug. 5, 2013

(30) Foreign Application Priority Data
Aug. 10, 2012 (JP) 2012-178899
May 31, 2013 (JP) 2013-116230

(51) Int. Cl. H01J 37/02

(52) U.S. Cl. CPC H01J 37/02
USPC 156/345.33

(57) ABSTRACT

Provided is a substrate processing apparatus in which the concentration of processing gas is matched in a substrate surface at the time of initiating the ejection of the processing gas from a gas supply unit. The gas supply unit is provided with a gas ejecting surface facing the wafer disposed on a disposition unit. The gas supply unit is also provided with gas flow paths, and a flow path length and a flow path diameter of the diverged gas flow paths are set such that periods of time for gas flowing from a gas supply hole to a plurality of gas ejecting holes formed on the gas ejecting surface are matched with each other. Thus, the timings when the processing gas reaches the respective gas ejecting holes immediately after initiating the ejection of the processing gas are matched.

### CROSS-REFERENCE TO RELATED APPLICATIONS

This application is based on and claims priority from Japanese Patent Application Nos. 2012-178899 and 2013-116230, filed on Aug. 10, 2012 and May 31, 2013, respectively, with the Japan Patent Office, the disclosures of which are incorporated herein in their entireties by reference.

### TECHNICAL FIELD

The present disclosure relates to a substrate processing apparatus for processing a substrate by supplying a processing gas under the atmospheric pressure, and a gas supply apparatus used in the substrate processing apparatus.

### BACKGROUND

Due to the wave-like property of light irradiated on a resist film of a wafer during an exposure processing, variation in measurement dimension, called Line Width Roughness (LWR) occurs in a resist pattern formed after the development. When the resist film in which the pattern is roughened is used as a mask to an undercoat film, the etching shape is influenced by the roughness. As a result, the shape of a circuit pattern formed by the etching becomes also rough. Thus, as the circuit pattern becomes miniaturized, the influence of the roughness of the shape of the circuit pattern increases on the quality of semiconductor devices. As a result, the yield may be reduced.

Accordingly, a planarization processing of a surface of a resist pattern has been investigated in which the resist pattern is exposed to a solvent atmosphere, and the surface of the resist pattern is swelled and dissolved. Japanese Patent Laid-Open Publication No. 2005-19969 discloses an apparatus for performing such a processing in which a solvent gas is supplied from the upper side on a wafer disposed on a disposition unit within a processing chamber. The apparatus is configured such that the inside of a processing chamber is partitioned into upper and lower portions by a baffle plate formed with a plurality of holes, a disposition table is provided at the lower side of the baffle plate, and a solvent gas is supplied to the upper side of the baffle plate from a solvent supply unit. The solvent gas supplied to the upper side of the baffle plate in this manner flows through the baffle plate to the lower side, and is supplied to the entire surface of a wafer on the disposition table. With this configuration, the solvent gas may be supplied to the entire surface of the wafer, and thus may be supplied to the wafer surface uniformly to some extent. However, as the pattern becomes miniaturized, a requirement for precision of pattern shape tends to be further strict. Thus, it is required to perform a processing with a higher in-plane uniformity on a wafer. See, e.g. paragraph [0065] and FIG. 15 of Japanese Patent Laid-Open Publication No. 2005-19969.

Specifically, the solvent gas supplied from the solvent supply unit into the processing chamber is diffused in an upper area above the baffle plate, while a part of the solvent gas flows to the lower side through the baffle plate. A purge gas or atmospheric air exists in the upper area to be substituted by the solvent gas atmosphere within the processing chamber after a preceding wafer has been processed. Accordingly, until the atmosphere of the purge gas or the atmospheric air of the upper area is substituted by the solvent gas, the solvent gas is ejected from the holes at a position close to the solvent supply unit but is not ejected from the holes at a position far away from the solvent supply unit. Thus, until the atmosphere of the upper area is substituted by the solvent gas, the amount of the supplied solvent gas is higher at the position close to the solvent supply unit than at the position far away from the solvent supply unit on the wafer surface. This causes variation in concentration distribution of the solvent on the wafer surface. At the position close to the solvent supply unit, the solvent is supplied in a large amount with a high concentration. Thus, the resist pattern may be excessively swelled to be collapsed or dissolved. In particular, when the line width of the resist pattern is reduced to form a fine circuit pattern on the undercoat film, the ratio of a thickness of the solvent permeation area in relation to the thickness of the pattern increases. Thus, the pattern collapse or dissolution may easily occur. Meanwhile, at the position far away from the solvent supply unit, since the solvent gas is supplied in a small amount with a low concentration, the roughness of the resist pattern may not be sufficiently relieved.

### SUMMARY

The present disclosure provides a substrate processing apparatus configured to perform processing on a substrate by a processing gas under an atmospheric pressure within a processing chamber. The substrate processing apparatus includes: a disposition unit provided within the processing chamber configured to dispose the substrate; and a gas supply unit equipped with a gas ejecting surface facing the substrate and provided to supply the processing gas to the substrate disposed on the disposition unit. The gas supply unit includes a plurality of gas ejecting holes formed to be distributed over an entire surface of an area of the gas ejecting surface facing the substrate, and gas flow paths having an upstream side communicated with a common gas supply hole and diverged on the way to have a downstream side opened as the plurality of gas ejecting holes, and a flow path length and a flow path diameter of the diverged gas flow path are set such that periods of time for gas flowing from the gas supply hole to the plurality of gas ejecting holes match each other.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical-sectional side view illustrating a solvent supply apparatus according to the present disclosure.

FIG. 2 is a plan view illustrating the solvent supply apparatus.

FIG. 3 is a vertical-sectional side view illustrating a processing unit of the solvent supply apparatus according to one exemplary embodiment.

FIG. 4 is a perspective view illustrating a part of the processing unit.

FIG. 5 is a side view schematically illustrating gas flow paths of a gas supply unit provided in the processing unit.

FIG. 6 is a perspective view illustrating a part of the gas supply unit.

FIG. 7 is a plan view illustrating horizontal flow paths of the gas supply unit.

FIG. 8 is a plan view illustrating horizontal flow paths of the gas supply unit.

FIG. 9 is a plan view illustrating horizontal flow paths of the gas supply unit.

FIG. 10 is a plan view illustrating horizontal flow paths of the gas supply unit.

FIG. 11 is a schematic perspective view illustrating horizontal flow paths of the gas supply unit.

FIG. 12 is a vertical-sectional side view illustrating a part of the gas supply unit.

FIG. 13 is a view illustrating a configuration of a solvent gas supply system of the processing unit.

FIG. 14 is a process view illustrating processing in the processing unit.

FIG. 15 is a process view illustrating processing in the processing unit.

FIG. 16 is a process view illustrating processing in the processing unit.

FIG. 17 is a process view illustrating processing in the processing unit.

FIG. 18 is a vertical-sectional side view illustrating flows of a processing gas and a purge gas in the processing unit.

FIG. 19 is a schematic view illustrating the state of a resist pattern.

FIG. 20 is a vertical-sectional side view of a processing unit according to another exemplary embodiment.

FIG. 21 is a plan view of a heater and a characteristic view of an LWR.

FIG. 22 is a characteristic view illustrating a change of a supply flow rate of a processing gas with elapse of time.

FIG. 23 is a characteristic view illustrating a change of a supply flow rate of a processing gas with elapse of time.

FIG. 24 is a characteristic view illustrating a change of a supply flow rate of a processing gas with elapse of time.

FIG. 25 is a vertical-sectional side view illustrating a processing unit according to a further exemplary embodiment.

FIG. 26 is a plan view illustrating horizontal flow paths of gas flow paths.

FIG. 27 is a vertical-sectional side view illustrating a part of the gas supply unit.

FIG. 28 is a vertical-sectional side view illustrating a part of the gas supply unit.

FIG. 29 is a vertical-sectional side view illustrating a part of the gas supply unit.

FIG. 30 is a vertical-sectional side view of a processing unit according to a still further exemplary embodiment.

FIG. 31 is a vertical-sectional side view illustrating a flow of a processing gas in the processing unit.

FIG. 32 is a characteristic view illustrating evaluation test results.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure has been made by taking the above-described problems into consideration. An object of the present disclosure is to provide a technology of performing processing on a substrate by supplying a processing gas from a gas supply unit facing the substrate under atmospheric pressure, in which concentrations of the processing gas on the substrate surface at the time of initiating the ejection of the processing gas from the gas supply unit may be matched.

The present disclosure provides a substrate processing apparatus configured to perform processing on a substrate by a processing gas under an atmospheric pressure within a processing chamber. The substrate processing apparatus includes: a disposition unit provided within the processing chamber configured to dispose the substrate; and a gas supply unit equipped with a gas ejecting surface facing the substrate and provided to supply the processing gas to the substrate disposed on the disposition unit. The gas supply unit includes a plurality of gas ejecting holes formed to be distributed over an entire surface of an area of the gas ejecting surface facing the substrate, and gas flow paths having an upstream side communicated with a common gas supply hole and diverged on the way to have a downstream side opened as the plurality of gas ejecting holes, and a flow path length and a flow path diameter of the diverged gas flow path are set such that periods of time for gas flowing from the gas supply hole to the plurality of gas ejecting holes match each other.

In the substrate processing apparatus, the gas flow path formed to be diverged in a stepwise diagram shape that determines a tournament combination from the gas supply hole to the gas ejecting holes.

In the substrate processing apparatus, when a direction perpendicular to the substrate is defined as a vertical direction, the gas flow paths includes: a group of first flow paths which have a vertical flow path and a plurality of horizontal flow paths, the vertical flow path extending vertically and having an upper end side communicated with the gas supply hole, and the plurality of horizontal flow paths extending horizontally radially from a lower end side of the vertical flow path, and a group of second flow paths which have a plurality of vertical flow paths extending downwardly from downstream ends of the horizontal flow paths, respectively, in the group of the first flow paths, and a plurality of horizontal flow paths extending radially and horizontally from lower end sides of the vertical flow paths.

In the substrate processing apparatus, the gas supply unit includes a plurality of plates which are vertically laminated with each other, the plurality of plates include a plate formed with groove portions or slits, and a plate in which through holes forming the vertical flow paths are formed, and the groove portions or the slits formed on one plate together with a plate surface of another plate to be piled up on the plate form the horizontal flow paths.

In the substrate processing apparatus, the plurality of gas ejecting holes include a plurality of gas ejecting holes included in a first area as a projection area of a region close to a center of the substrate, and a plurality of gas ejecting holes included in a second area as a projection area of a region close to an outer periphery of the substrate other than the region close to the center of the substrate, and in the plurality of gas ejecting holes included in the first area, flow path lengths of the gas flow paths are matched from the gas supply hole to the gas ejecting holes, respectively.

In the substrate processing apparatus, the processing performed on the substrate by supplying the processing gas is processing performed to improve the roughness of the pattern mask by supplying a solvent gas for dissolving a resist film on the substrate that has a pattern mask formed through exposure and development processing.

According to another aspect, the present disclosure provides a substrate processing apparatus configured to perform processing on a substrate by a processing gas under an atmospheric pressure within a processing chamber. The substrate processing apparatus includes: a disposition unit provided within the processing chamber configured to dispose the substrate; and a gas supply unit equipped with a gas ejecting surface facing the substrate and provided to supply the processing gas to the substrate disposed on the disposition unit. The gas supply unit includes: a plurality of gas ejecting holes formed to be distributed over an entire surface of an area of the gas ejecting surface facing the substrate, and gas flow paths configured by using a plurality of plates which are vertically laminated with each other having an upstream side communicated with a common gas supply hole, and diverged on the way to have a downstream side opened as the plurality of gas ejecting holes. When a direction perpendicular to the substrate is defined as a vertical direction, the gas flow path includes: a group of first flow paths which have a vertical flow path and a plurality of horizontal flow paths, the vertical flow path extending vertically and having an upper end side communicated with the gas supply hole and the plurality of horizontal flow paths extending horizontally radially from a lower end side of the vertical flow path, and a group of second flow paths which have a plurality of vertical flow paths extending downwardly from downstream ends of the horizontal flow paths, respectively, in the group of the first flow paths and a plurality of horizontal flow paths extending radially and horizontally from lower end sides of the vertical flow paths. The plurality of plates include a plate formed with groove portions or slits and a plate in which through holes forming the vertical flow paths are formed. The groove portions or the slits formed on one plate together with a plate surface of another plate to be piled up on the plate form the horizontal flow paths, and flow path lengths of the gas flow paths are matched from the gas supply hole to the gas ejecting holes, respectively.

In the substrate processing apparatus, the plurality of gas ejecting holes include a plurality of gas ejecting holes included in a first area as a projection area of a region close to a center of the substrate, and a plurality of gas ejecting holes included in a second area as a projection area of a region close to an outer periphery of the substrate other than the region close to the center of the substrate, and horizontal flow paths included in the second area in gas flow paths extending from the gas supply hole to the plurality of gas ejecting holes included in the second area have a smaller flow path diameter than horizontal flow paths in gas flow paths extending from the gas supply hole to the plurality of gas ejecting holes included in the first area.

In the substrate processing apparatus, the plurality of gas ejecting holes include the plurality of gas ejecting holes included in the first area as the projection area of the region close to the center of the substrate, and the plurality of gas ejecting holes included in the second area as the projection area of the region close to the outer periphery of the substrate other than the region close to the center of the substrate, and vertical flow paths included in the second area in the gas flow paths extending from the gas supply hole to the plurality of gas ejecting holes included in the second area have a smaller flow path diameter than vertical flow paths in the gas flow paths extending from the gas supply hole to the plurality of gas ejecting holes included in the first area.

In the substrate processing apparatus, the plurality of gas ejecting holes include a plurality of gas ejecting holes included in a first area as a projection area of a region close to a center of the substrate, and a plurality of gas ejecting holes included in a second area as a projection area of a region close to an outer periphery of the substrate other than the region close to the center of the substrate, and vertical flow paths included in the second area in gas flow paths extending from the gas supply hole to the plurality of gas ejecting holes included in the second area have a smaller flow path diameter than vertical flow paths in gas flow paths extending from the gas supply hole to the plurality of gas ejecting holes included in the first area.

In the substrate processing apparatus, the processing performed on the substrate by supplying the processing gas is processing where a solvent gas for dissolving a resist film is supplied on the substrate that has a pattern mask formed through exposure and development processing, so as to improve roughness of the pattern mask.

According to a further aspect, the present disclosure provides a gas supply apparatus configured to supply a processing gas to a substrate disposed within a processing chamber set to an atmospheric pressure. The gas supply apparatus includes a gas ejecting surface facing the substrate disposed within the processing chamber; a plurality of gas ejecting holes formed to be distributed on the gas ejecting surface; and gas flow paths which have an upstream side communicated with a common gas supply hole, and diverged on the way to have a downstream side opened as the plurality of gas ejecting holes. A flow path length and a flow path diameter of the diverged gas flow paths are set such that periods of time for gas flowing from the gas supply hole to the plurality of gas ejecting holes are matched each other.

According to a still further aspect, the present disclosure provides a gas supply apparatus configured to supply a processing gas to a substrate disposed within a processing chamber set to an atmospheric pressure. The gas supply apparatus includes a gas ejecting surface facing the substrate disposed within the processing chamber; a plurality of gas ejecting holes formed to be distributed on the gas ejecting surface; and gas flow paths configured by using a plurality of plates which are laminated with each other in a direction perpendicular to the substrate and having an upstream side communicated with a common gas supply hole, and diverged on the way to have a downstream side opened as the plurality of gas ejecting holes, When the direction perpendicular to the substrate is defined as a vertical direction, the gas flow paths include a group of first flow paths which have a vertical flow path and a plurality of horizontal flow paths, the vertical flow path extending vertically and having an upper end side communicated with the gas supply hole, and the plurality of horizontal flow paths extending horizontally radially from a lower end side of the vertical flow path, and a group of second flow paths which have a plurality of vertical flow paths extending downwardly from downstream ends of the horizontal flow paths, respectively, in the group of the first flow paths, and a plurality of horizontal flow paths extending radially and horizontally from lower end sides of the vertical flow paths. The plurality of plates include a plate formed with groove portions or slits, and a plate in which through holes forming the vertical flow paths are formed, The groove portions or the slits formed on one plate together with a plate surface of another plate to be piled up on the plate form the horizontal flow paths, and flow path lengths of the gas flow paths are matched from the gas supply hole to the gas ejecting holes, respectively.

In the present disclosure, a flow path length and a flow path diameter of diverged gas flow paths are set so that when processing is performed on a substrate under atmospheric pressure by a processing gas, periods of time for gas flowing from a gas supply hole to a plurality of gas ejecting holes, respectively, formed on a gas ejecting surface facing the substrate are matched each other. For this reason, the timings when the processing gas reaches the respective gas ejecting holes immediately after initiating the ejection of the processing gas are matched. That is, periods of time when the atmosphere (for example, a purge gas or an atmospheric air) within flow paths is substituted with the processing gas are matched from the gas supply hole to the respective gas ejecting holes. Accordingly, the uniformity of the processing gas concentration on the substrate surface is high, and thus the processing may be performed with a high in-plane uniformity.

### First Exemplary Embodiment

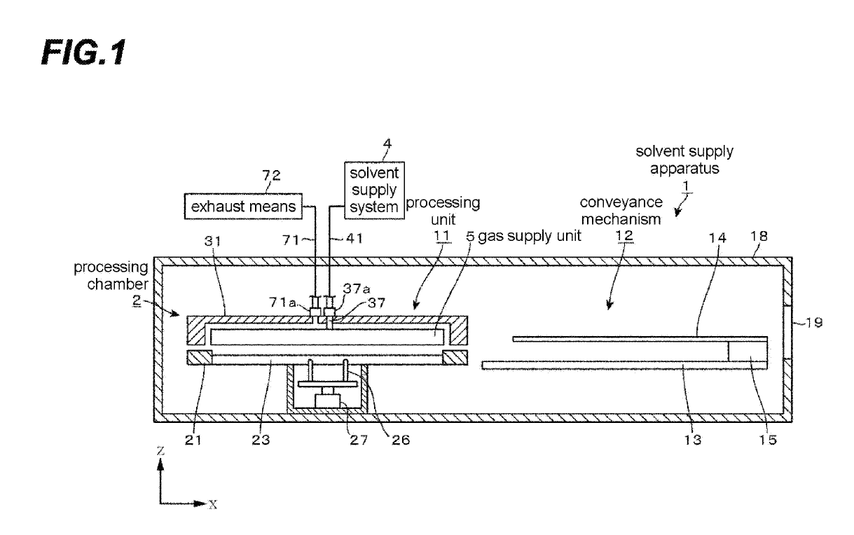

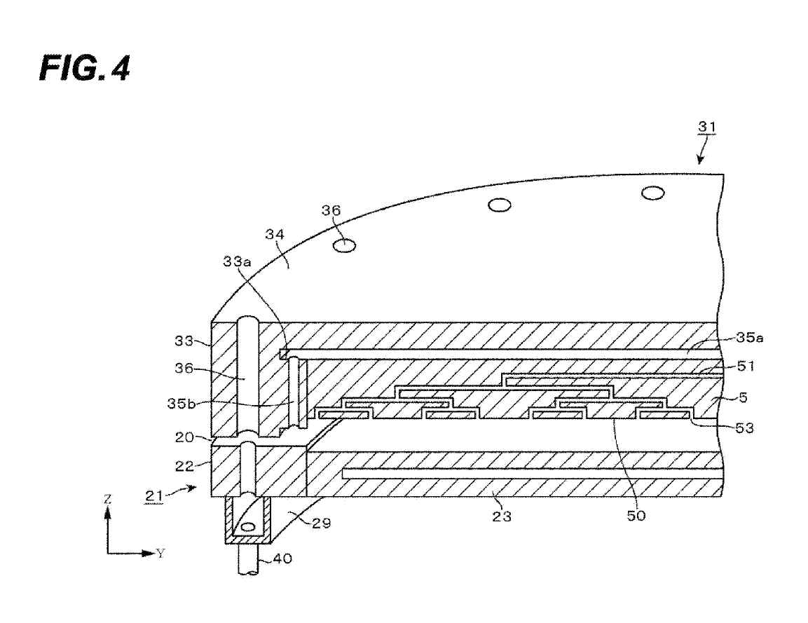

A solvent supply apparatus, to which a substrate processing apparatus according to a first exemplary embodiment of the present disclosure is employed, will be described with reference to FIGS. 1 to 13. A solvent supply apparatus 1 includes a processing unit 11 configured to supply a gas to a wafer W to perform a processing, and a conveyance mechanism 12 configured to convey a semiconductor wafer (hereinafter, referred to as “wafer”) W as a substrate between the processing unit 11 and the outside of the processing unit 11. The processing unit 11 corresponds to the substrate processing apparatus of the present disclosure. On a surface of the wafer W conveyed to the processing unit 11, a resist film is formed. The resist film has a resist pattern as a pattern mask that is formed through exposure and developing processings.

The processing unit 11 includes a processing chamber 2 formed in, for example, a flat circular shape. The processing chamber 2, as illustrated in FIGS. 1 to 3, includes a vessel body 21 and a cover 31. The vessel body 21 includes a side wall portion 22 that forms a peripheral edge of the vessel body 21, and a disposition unit 23 that forms a lower wall portion surrounded by the side wall portion 22. The disposition unit 23 is configured such that the wafer W is horizontally disposed on the top surface of the disposition unit. Also, a heater 24 that constitutes a heating mechanism of the disposition unit 23 is provided in the disposition unit 23, and heats the disposed wafer W to a predetermined temperature. Pins 26 are inserted through three holes 25, respectively, which are provided in the disposition unit 23. The pins 26 project from or retract into the disposition unit 23 by an elevating mechanism 27, and serve to deliver the wafer W to/from the conveyance mechanism 12.

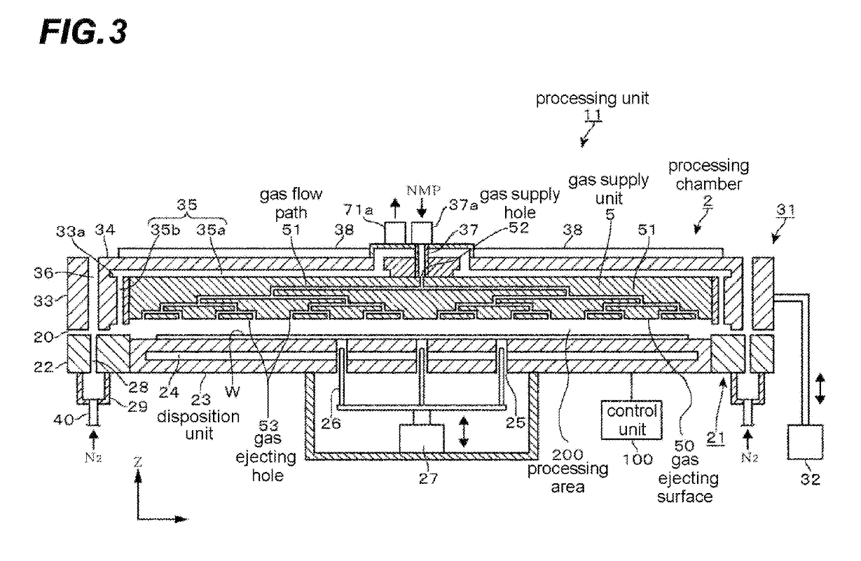

The cover 31 may be moved up and down by an elevating mechanism 32 from a carrying-in/out position where the wafer W is carried into the processing chamber 2, to a processing position where the wafer W is processed (the position illustrated in FIG. 3). The cover 31 includes a side wall portion 33 constituting the peripheral edge of the cover 31, and an upper wall portion 34 surrounded by the side wall portion 33. The lower end of the side wall portion 33 is placed at a position lower than the lower end of the upper wall portion 34. When the cover 31 is placed at the processing position so as to perform a processing of the wafer W, the lower end of the upper wall portion 34 and the upper end of the side wall portion 22 of the vessel body 21 come close to each other with a gap 20 therebetween. In this manner, a processing area 200 is formed within the processing chamber 2 when the cover 31 is placed at the processing position.

A gas supply unit (shower head) 5 is provided within the cover 31 so as to form an exhaust space 35a between the upper wall portion 34 and the gas supply unit 5. Also, the side wall portion 33 of the cover 31 is configured to protrude inwards, and its protrusion 33a supports the lateral portion of the gas supply unit 5. In addition, exhaust holes 35b which vertically penetrate the protrusion 33a and have upper ends communicated with the exhaust space 35a are formed in the protrusion 33a to be spaced apart from each other in the circumferential direction. An exhaust passage 35 is formed by the exhaust space 35a and the exhaust holes 35b. Accordingly, the atmosphere within the processing area 200 is exhausted through the exhaust holes 35b which are spaced apart from each other in the circumferential direction to surround the processing area 200.

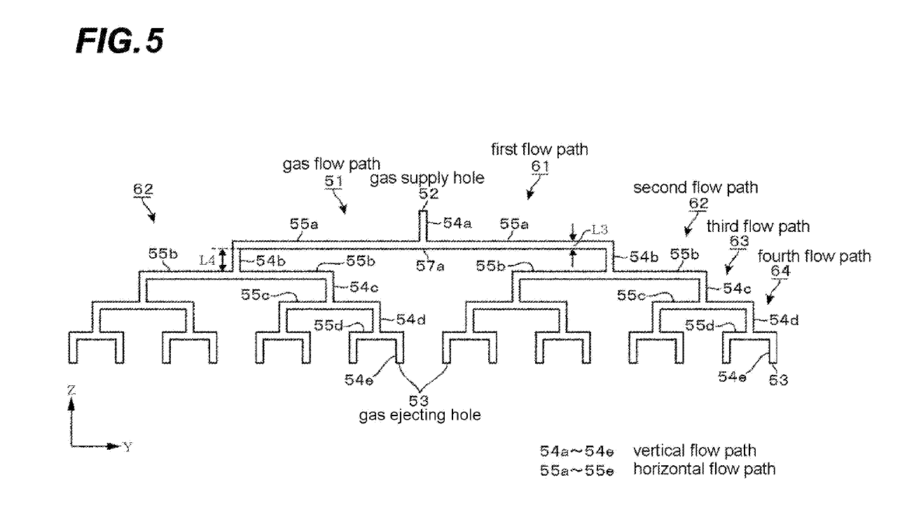

The gas supply unit 5 corresponds to a gas supply apparatus of the present disclosure, which includes a gas ejecting surface 50 facing the wafer W disposed on the disposition unit 23. The gas ejecting surface 50 has formed in, for example, a circular shape in a plan view. The size of the gas ejecting surface in the plan view is set to be larger than the wafer W on the disposition unit 23. Gas flow paths 51 are formed within the gas supply unit 5. FIG. 5 is a side view schematically illustrating only the gas flow paths 51. The upstream side of the gas flow paths 51 is opened at the central portion of the top surface of the gas supply unit 5 to form a common gas supply hole 52. Also, a plurality of gas ejecting holes 53 are formed to be distributed over the entire surface of an area of the gas ejecting surface 50 facing the wafer W. The phrase “to be distributed over the entire surface of an area facing the wafer W” means that the gas ejecting holes 53 are formed to be distributed so that the outermost one of the gas ejecting holes 53 is positioned on the gas ejecting surface 50, outside an area facing the to-be-processed area (e.g. an area to be formed with devices) of the wafer W on the disposition unit 23.

In the gas supply unit 5, a flow path length and a flow path diameter (the cross-sectional area of a flow path) of diverged gas flow paths are set so that periods of time for gas flowing from the gas supply hole 52 to the respective gas ejecting holes 53 are matched each other.

Specifically, the gas flow paths 51 are formed to be diverged in a stepwise diagram shape that determines a tournament combination from the gas supply hole 52 to the gas ejecting holes 53. Here, an example where the gas flow paths 51 are formed to be diverged in a stepwise shape with four stages as illustrated in FIGS. 3 to 5 will be used for description. As described above, the gas flow paths 51 include a combination of vertical flow paths 54 which vertically extend, and horizontal flow paths 55, when a direction perpendicular to the wafer W is defined as a vertical direction. Also, the gas flow paths 51 include first flow paths 61 which have a vertical flow path 54a having an upper end side communicated with the gas supply hole 52, and a plurality of horizontal flow paths 55a extend horizontally and radially from a lower end side of the vertical flow path 54a. Also, the gas flow paths 51 include four groups of second flow paths 62 which have a plurality of vertical flow paths 54b extending downwardly from downstream ends of the respective horizontal flow paths 55a of the first flow paths 61, and a plurality of horizontal flow paths 55b extending radially and horizontally from the lower end sides of the vertical flow paths 54b.

Also, a group of third flow paths 63 are provided at the downstream side of the group of the second flow paths 62, and a group of fourth flow paths 64 are provided at the downstream side of the group of the third flow paths 63. The third flow paths 63 include a plurality of vertical flow paths 54c extending downwardly from downstream ends of the respective horizontal flow paths 55b of the second flow paths 62, and a plurality of horizontal flow paths 55c extending radially and horizontally from the lower end sides of the vertical flow paths 54c. Also, the fourth flow paths 64 include a plurality of vertical flow paths 54d extending downwardly from downstream ends of the respective horizontal flow paths 55c of the third flow paths 63, and a plurality of horizontal flow paths 55d extending radially horizontally from the lower end sides of the vertical flow paths 54d. Also, a plurality of vertical flow paths 54e that extend downwardly from the downstream ends of the horizontal flow paths 55d are provided at the respective horizontal flow paths 55d of the fourth flow paths 64. The downstream end of each of the vertical flow paths 54e corresponds to each of the gas ejecting holes 53.

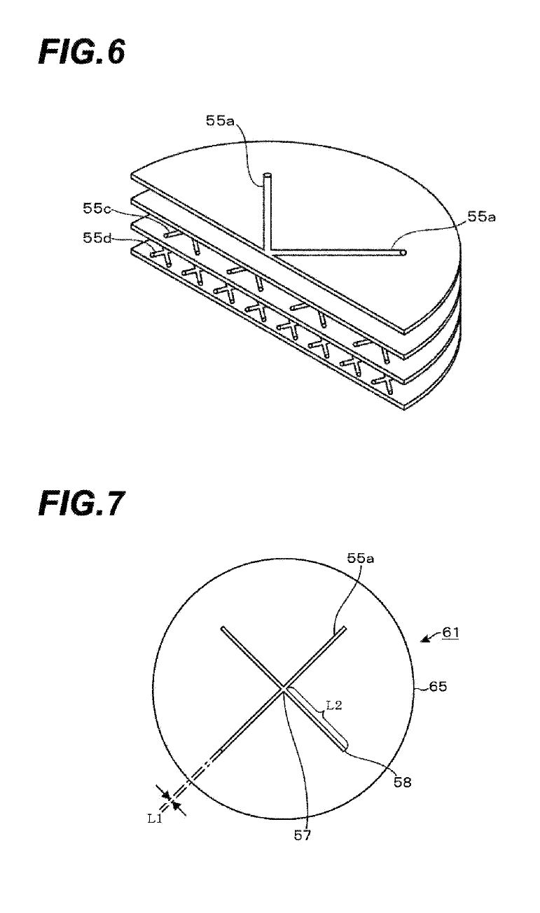

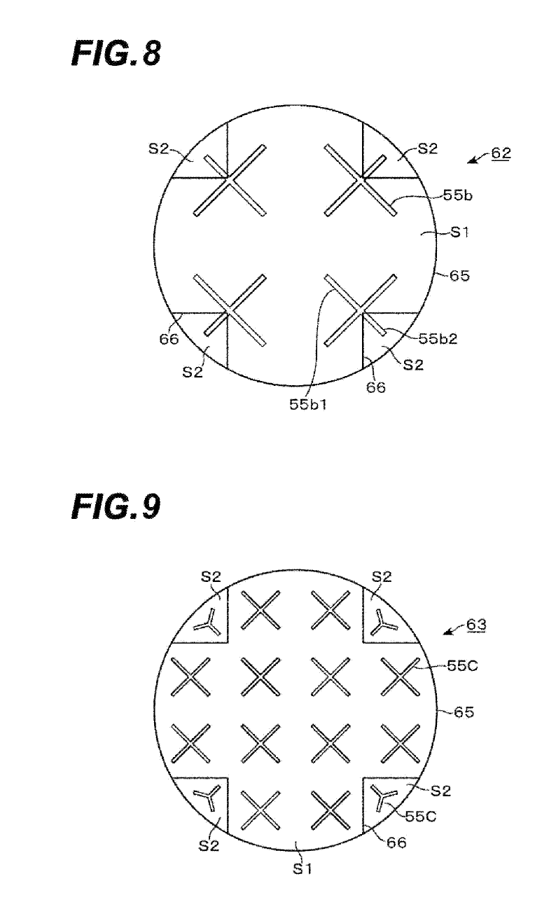

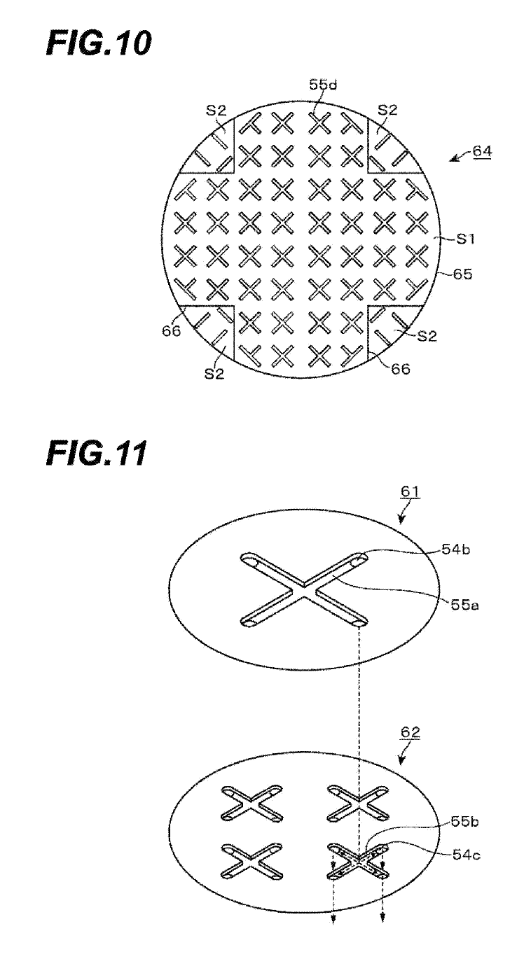

In one example of the horizontal flow paths 55, the first flow paths 61 are illustrated in FIGS. 6, 7 and 11, the second flow paths 62 are illustrated in FIGS. 8 and 11, the third flow paths 63 are illustrated in FIG. 9, and the fourth flow paths 64 are illustrated in FIG. 10. Here, the reference numeral 65 in FIGS. 7 to 10 indicates an outer edge of the gas supply unit 5 (the gas ejecting surface 50), and solid lines 66 in FIGS. 8 to 10 divisionally indicate a projection area of a first area including a central area of the gas ejecting surface 50. The outside of the first area of the gas ejecting surface 50 is a second area. In FIGS. 8 to 10, the projection areas of the first area and the second area are illustrated. Thus, the projection areas may be referred to as a first projection area S1 and a second projection area S2, but in order to simplify terms, areas corresponding to S1 and S2 shown in a plan view will be referred to as a first area S1 and a second area S2, respectively.

As illustrated in the drawings, the horizontal flow paths 55a and 55b of each of the first flow paths 61 and the second flow paths 62 are configured in a cross shape. For example, the intersection point (center) 57 of the horizontal flow paths 55a at the first stage is provided at a position facing the center of the wafer W disposed on the disposition unit 23. Also, the centers of crossroads configured by the horizontal flow paths 55b as illustrated in FIG. 8 are positioned at the positions below the distal ends (areas provided with the vertical flow paths 54b) of the horizontal flow paths 55a illustrated in FIG. 7, respectively. That is, the horizontal flow paths 55b extend in four directions starting from the center thereof.

Also, as illustrated in FIG. 9, the horizontal flow paths 55c of the third flow paths 63 are configured in a cross shape in the first area S1. In addition, the horizontal flow paths 55c in the second area S2 are diverged in three directions from the starting point thereof. Referring back to FIG. 8, the centers of the crossroads or the three directionally diverged flow paths as illustrated in FIG. 9 are located at the positions below the distal ends (areas provided with vertical flow paths 54c) of the horizontal flow paths 55b constituting the crossroads, respectively. That is, the horizontal flow paths 55c extend in four or three directions starting from the center thereof.

Also, most of the horizontal flow paths 55d of the fourth flow paths 64 are configured in a cross shape in the first area S1. However, some of the horizontal flow paths 55d are also formed to be diverged in three directions in a T shape from the starting point in a part at the circumferential edge side. In the second area S2, the horizontal flow paths 55d are formed in three straight-line flow paths. More specifically, the center of each cross shape or T shape of the horizontal flow paths 55d in the first area Si corresponds to a position below one distal end (an area provided with a vertical flow path 54d) of the horizontal flow paths 55c of the cross shape as illustrated in FIG. 9. Also, the position of a central point of each of the three straight-line flow paths in the second area S2 as illustrated in FIG. 10 corresponds to a position below one distal end (an area provided with a vertical flow path 54d) of the three-directionally diverged flow paths as illustrated in FIG. 9. A vertical flow path 54e is formed at each end of the horizontal flow path 55d of the cross shape or T shape, and each end of the straight-line flow paths in the second area S2.

In this manner, the diverged gas flow paths that extend from the gas supply hole 52 to the respective gas ejecting holes 53 are formed.

In the present exemplary embodiment, the respective horizontal flow paths 55 of the first to fourth flow paths 61 to 64 are configured to be symmetrical four times with respect to the center of the gas ejecting surface 50 of the gas supply unit 5. Also, in each of the groups of the first to fourth flow paths 61 to 64, the horizontal flow paths 55 within the first area S1 are configured to have an identical flow path width L1, an identical length L2 from an intersection point 57 to a downstream end 58, and an identical flow path depth L3. Also, in each of the groups of the first to fourth flow paths 61 to 64, the vertical flow paths 54 are configured to have an identical shape in a plan view and an identical length (depth) L4.

With the configuration described above, in the first area of the gas ejecting surface 50, the respective diverged gas flow paths 51 extending from the gas supply hole 52 to the respective gas ejecting holes 53 are matched each other in flow path length and flow path diameter. Accordingly, in the first area, periods of time for gas flowing from the gas supply hole 52 to the respective gas ejecting holes 53 may be matched each other. The period of time for gas flowing refers to a length of time required until the gas supplied to the gas supply hole 52 is ejected from the gas ejecting holes 53.

The above described layout of the horizontal flow paths designated by reference numerals 55a, 55b, and 55c is merely an example, and the horizontal flow paths are not limited to the layout. For example, although each of the horizontal flow paths 55a to 55c is diverged in a cross shape, they may be diverged in an open state at 180° or may be diverged in an open state at 120° (that is, diverged in a Y shape) at a position corresponding to an end of the vertical flow paths. Further, five or more diverged flow paths may be configured to radially extend so that, for example, adjacent pairs of diverged flow paths have the same open angle (at an equal interval in the circumferential direction), at a position corresponding to the end of each of the vertical flow paths.

However, the configuration where the plurality of diverged flow paths extend radially from the end of each of the vertical flow paths is not limited to the configuration where the diverged flow paths extend at an equal interval in the circumferential direction, and the configuration where the lengths of the diverged flow paths extending radially from the end of each of the vertical flow paths are matched each other.

Also, the flow path length of the horizontal flow paths in the second area S2 of the gas ejecting surface 50 may be required to be shorter than that in the first area S1, due to the limitation of processing.

As described above, since the second area S2 of the gas ejecting surface 50 is close to the outer edge of the gas supply unit 5, the degrees of matching of flow path lengths and flow path diameters between gas flow paths of the second area S2 and gas flow paths of the first area Si may be lower than those between gas flow paths within the first area S1, due to limitation of processing. However, as described below, in order to match periods of time for flowing from the gas ejecting holes 53 in both the first area Si and the second area S2, it is preferable that flow path volumes of the gas flow paths extending from the gas supply hole 52 to the respective gas ejecting holes 53 are matched. For example, when a maximum value of flow path volumes of the gas flow paths corresponding to the respective gas ejecting holes 53 formed in the gas ejecting surface 50 is set to Vmax, and a minimum value is set to Vmin, it is preferable that (Vmax−Vmin)/Vmin<50%. It is more preferable that the left side value of the equation is 30% or less, and it is further preferable that the left side value is 10% or less.

Also, when a maximum value of flow path lengths of the gas flow paths corresponding to the respective gas ejecting holes 53 formed in the gas ejecting surface 50 is set to Lmax, and a minimum value is set to Lmin, it is preferable that (Lmax−Lmin)/Lmin<50%. It is more preferable that the left side value of the equation is 30% or less, and it is further preferable that the left side value is 10% or less.

According to the shape of the gas supply unit 5 or the design of the gas flow paths 51, the first area S1 may have a different shape and the second area S2 may be not formed.

In this manner, in the present disclosure, the flow path lengths and the flow path diameters of the diverged gas paths extending from the gas supply hole 52 to the respective gas ejecting holes 53 are matched so that the periods of time for gas flowing from the gas supply hole 52 to the respective gas ejecting holes 53 may be matched each other. Also, in an area where the flow path lengths and the flow path diameters may be not matched due to the design of the gas supply unit 5, the periods of time for flowing are matched by controlling the flow velocity of a gas by adjusting the flow path diameters.

Accordingly, the flow path lengths and the flow path diameters of the diverged gas flow paths 51 are set, respectively, so that the periods of time for gas flowing from the gas supply hole 52 to the respective gas ejecting holes 53 may be matched each other. Here, the matching of the periods of time for gas flowing indicates that (Tmax−Tmin)/Tmin<50% when a maximum period of time required until a gas supplied to the gas supply hole 52 is ejected from the respective gas ejecting holes 53 is set as Tmax and a minimum period of time is set as Tmin. The variation to this extent allows the effect of the present disclosure to be sufficiently achieved. Also, it is more preferable that (Tmax−Tmin)/Tmin<30%, and it is further more preferable that the left side value is 10% or less.

For example, the period of time for flowing in one gas ejecting hole 53 among the gas ejecting holes 53 is measured in a state in which other gas ejecting holes 53 are closed with, for example, a tape. In the same manner, the periods of time for flowing in other gas ejecting holes 53 one by one are also sequentially measured. In this manner, the periods of time for flowing may be collected and verified for all the gas ejecting holes 53. In measuring the periods of time for flowing, the timing of initiating gas supply is set to the time of issuing an ON command of a valve attached on the gas supply hole 52, and the timing of gas ejecting may be detected by providing an anemometer on the disposition unit 23.

Also, in order to achieve the object of the present disclosure, it is believed that the design is preferably made so that the periods of time for flowing may be matched among the gas ejecting holes 53, if possible. However, when it is difficult to perform a processing that equalizes volumes among flow paths due to the processing precision or the structure, the mismatching among volumes in the respective flow paths may not be avoided. Even in such a case, when the above described equation is satisfied, the periods of time for flowing may be matched.

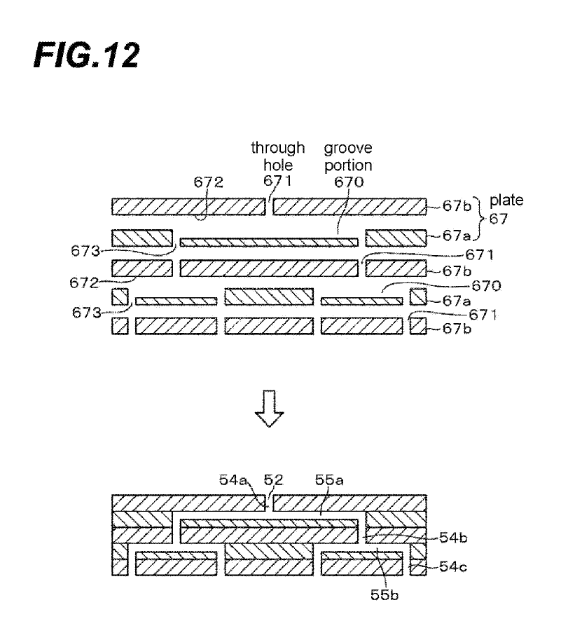

The gas supply unit 5 as described above has a configuration where a plurality of plates 67 made of, for example, a metal are laminated as illustrated in FIG. 12 exemplifying the first flow paths 61 and the second flow paths 62. The plurality of plates 67 include, for example, a plate 67a that has groove portions 670 formed on the surface thereof, and a plate 67b that has through holes 671 formed therein. The through holes 671 form the vertical flow paths 54. Also, the groove portions 670 formed on one plate 67a, together with a plate surface 672 of the other plate 67b to be piled up at the upper side of the plate 67a, form the horizontal flow paths 55. Also, through holes 673 are formed in the plate 67a formed with the groove portions 670 so as to communicate with the through holes 671 of the plate 67b at the lower side. The groove portions 670 and the through holes 671 and 673 are formed on the plates 67 through etching, and the plates 67 that have been subjected to etching in this manner are bonded together by diffusion bonding to form the gas supply unit 5. The diffusion bonding is a method of bonding two metallic surfaces through diffusion of atoms by heating under pressure.

In a specific configuration example, for example, as each of the plates 67, a stainless steel plate that has a thickness ranging from 0.2 mm to 2.0 mm, and a diameter of 320 mm (in a case of a 300 mm wafer) is used. The width L1 of the horizontal flow paths 55 may be set to a range from 2 mm to 4 mm, the depth L3 may be set to a range from 0.1 mm to 1.8 mm. The diameter of an opening of the vertical flow paths 54 may be set to a range from 0.5 mm to 3.0 mm, and the length L4 may be set to a range from 0.1 to 1.0 mm. The diameter of the gas ejecting holes 53 may be set to a range from 0.5 mm to 2.0 mm. The number of the gas ejecting holes 53 formed in the gas ejecting surface 50 may be varied according to the shape of the horizontal flow paths 55, or the number of steps in stepwise shape diversion, but, for example, 500 to 3000 gas ejecting holes 53 may be arranged vertically and horizontally at equal intervals.

Referring back to the description of the processing chamber 2, a plurality of first purge gas flow paths 28 are formed along the circumferential direction at the side wall portion 22 of the vessel body 21. The first purge gas flow paths 28 are formed to vertically penetrate the side wall portion 22. A ring-shaped space 29 that communicates with the first purge gas flow paths 28 is formed below the side wall portion 22, and one end sides of a plurality of purge gas supply tubes 40 are connected below the space 29 to be spaced apart from each other in the circumferential direction. Also, a plurality of second purge gas flow paths 36 are formed along the circumferential direction at the side wall portion 33 of the cover 31. The second purge gas flow paths 36 are formed to vertically penetrate the side wall portion 33 at the positions corresponding to the first purge gas flow paths 28.

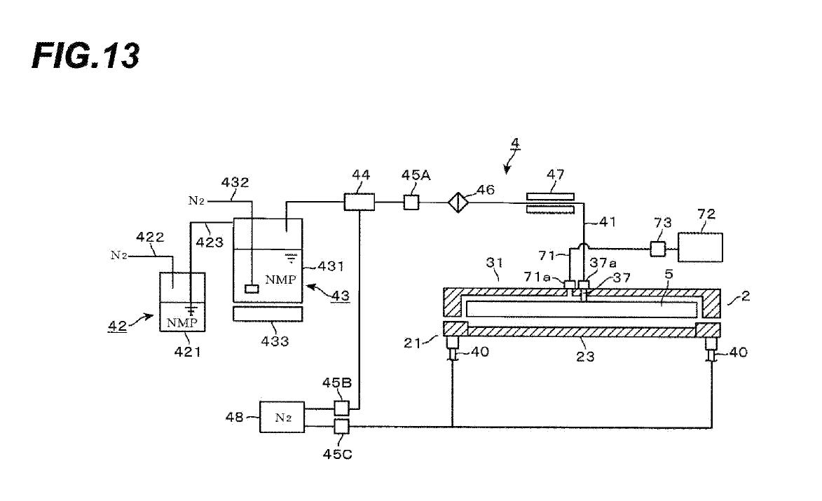

Also, as illustrated in FIG. 3, a gas supply path 37 is provided at the ceiling portion of the gas supply unit 5 to communicate with the gas supply hole 52. As illustrated in FIGS. 3 and 13, one end side (upper end side) of the gas supply path 37 is connected to a solvent gas supply system 4 via a supply passage 41 and a gas supply port 37a provided in the upper wall portion 34 of the processing chamber 2. A solvent supply source 42 is provided at the upstream end of the solvent gas supply system 4. The solvent supply source 42 is configured to include a tank 421 in which a solvent capable of swelling a resist through dissolution (e.g. NMP (N-methyl-2-pyrrolidone)) is contained, and to supply a gas for pressurization (e.g. nitrogen (N₂) gas) via a supply passage 422. When the N₂ gas is supplied into the tank 421, the inside of the tank 421 is pressurized so that a liquid solvent is sent to a solvent gas generating unit 43 via a supply passage 423.

The solvent gas generating unit 43 includes a bubbling tank 431 in which the liquid solvent is contained, a bubbling gas supply tube 432 configured to perform bubbling by blowing a carrier gas, for example, N₂ gas in the solvent, and a heater 433 configured to heat the solvent up to a predetermined temperature. In the solvent gas generating unit 43, the solvent contained within the bubbling tank 431 is heated, and the carrier gas is blown from the bubbling gas supply tube 432 so as to generate vapors of the solvent component at the predetermined temperature (e.g. 80° C.). The vapors of the solvent component (a solvent gas), together with the carrier gas, are supplied as a processing gas to the gas supply path 37 within the processing chamber 2 via the supply passage 41 provided with a three-way valve 44, a first flow rate adjuster 45A, a filter 46 and a warming heater 47.

The filter 46 is configured to remove particles in the processing gas. The warming heater 47 is a heating mechanism that heats the supply passage 41 to suppress the solvent from being condensed on the inner wall of the supply passage 41. As the warming heater 47, for example, a tape heater is used, and is wound around the outside of the supply passage 41 to be mounted. Accordingly, the supply passage 41 provided with the warming heater 47 is heated up to, for example, a temperature not lower than a dew point of the solvent (e.g. 100° C.).

The three-way valve 44 is connected, via a second flow rate adjuster 45B, to a purge gas supply source 48 that pumps N₂ gas as a purge gas (substitution gas) to the downstream side. The pumped purge gas is subjected to a flow rate control in the second flow rate adjuster 45B, and is supplied into the gas supply unit 5 via the supply passage 41 and the gas supply path 37. Also, the other end side of each of the purge gas supply tubes 40 is connected to the purge gas supply source 48 via a third flow rate adjuster 45C. In this manner, the purge gas supplied to the space 29 from the purge gas supply source 48 is diffused within the space 29, and then ejected to the surface of the side wall portion 22 through the first purge gas flow paths 28.

Also, an exhaust passage 71 is connected to the upper wall portion 34 of the cover 31 via an exhaust port 71a, and an exhaust unit 72 is connected to the exhaust space 35a via the exhaust passage 71. The exhaust passage 71 is provided with the exhaust unit 72. Also, a heater 38 that constitutes a warming heating mechanism is provided on the top surface of the cover 31 so as to suppress the solvent gas from being condensed within the exhaust space 35a. The inside of the exhaust space 35a is heated up to a temperature higher than the dew point of the solvent (e.g. 100° C.).

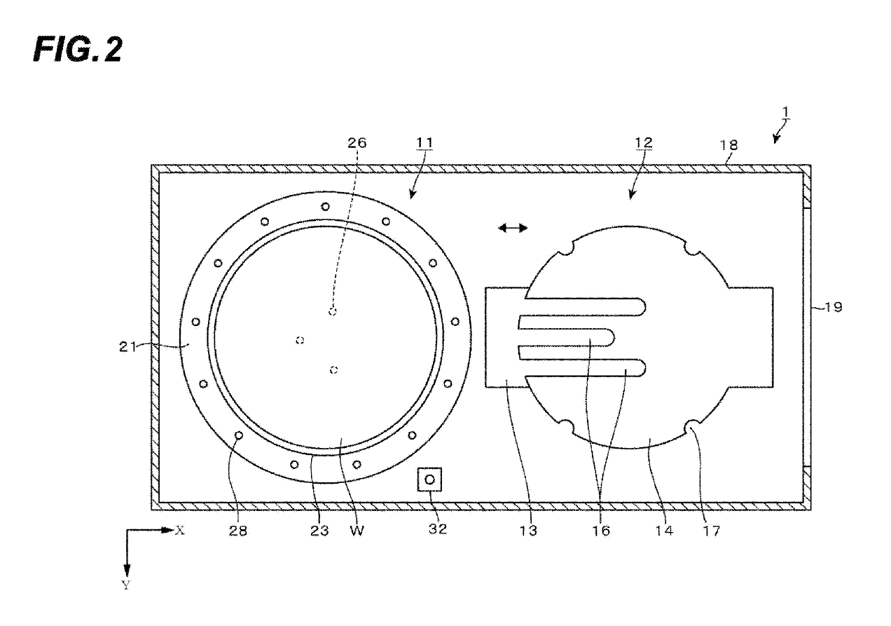

A base 13 is provided in the outside of the processing chamber 2, and is provided with the conveyance mechanism 12. The conveyance mechanism 12 includes a horizontal moving plate 14, and a moving mechanism 15 that horizontally moves the moving plate 14 on the base 13. When the moving plate 14 is positioned at a stand-by position as illustrated in FIGS. 1 and 2, the moving plate 14 may horizontally move between the stand-by position and a position above the disposition unit 23 of the processing chamber 2 by the moving mechanism 15.

Now, the moving plate 14 will be described. The reference numeral 16 in FIG. 2 indicates slits, which form areas through which the pins 26 configured to deliver the wafer W from/to the disposition unit 23 are passed. The reference numeral 17 in the drawing indicates cut-outs, which are provided to deliver the wafer W, for example, between the conveyance mechanism 12 and an external conveying arm (not illustrated). The processing unit 11 and the conveyance mechanism 12 are provided in parallel to the advance and retreat direction (the X-direction in FIGS. 1 and 2) of the moving plate 14 within a common case 18. Also, a conveyance opening 19 configured to deliver the wafer W from the external conveying arm to the conveyance mechanism 12 is formed in the case 18.

The solvent supply apparatus 1 is provided with a control unit 100 including a computer. The control unit 100 transmits control signals to respective units of the solvent supply apparatus 1, and controls supply/interruption of the various gases and the supply amount of each gas, temperatures of the various heaters 24 and 38 and the warming heater 47, the delivery of the wafer W between the moving plate 14 and the disposition unit 23, and operations such as exhausting within the processing chamber 2. Also, the control unit 100 is provided with a program that incorporates instructions (respective steps) to perform processing in the solvent supply apparatus 1 as described below. The program is stored in a computer storage medium, such as, for example, a flexible disk, a compact disk, a hard disk, an MO (magneto-optical disk), and installed in the control unit 100.

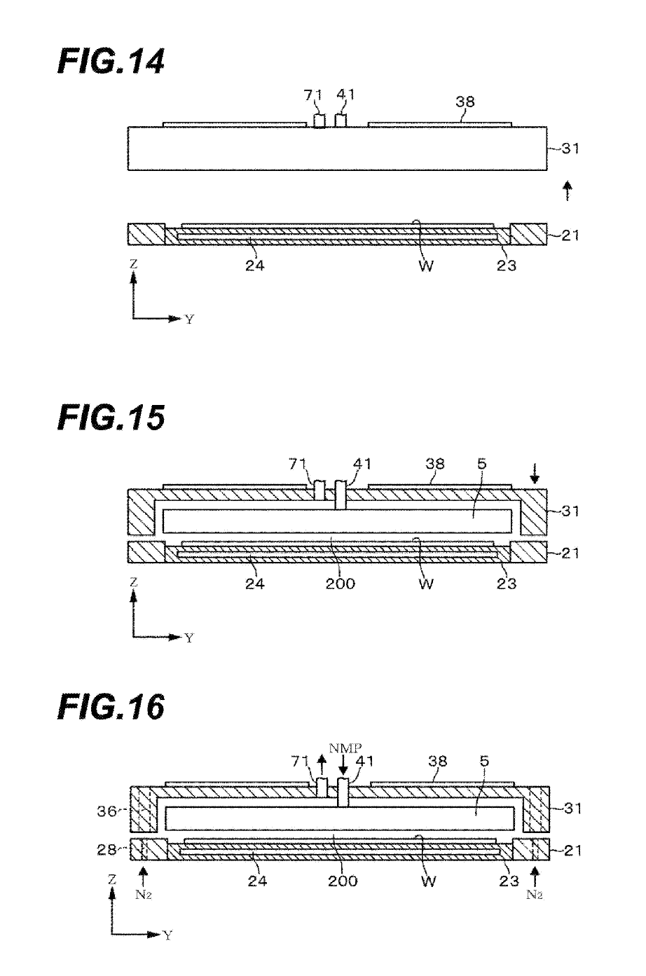

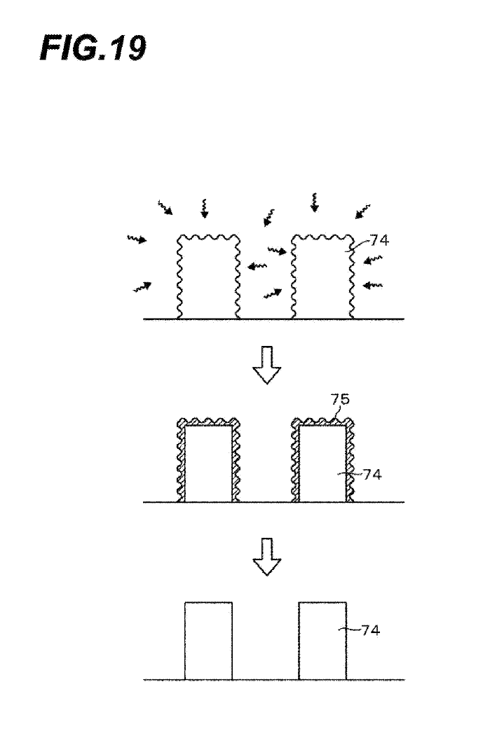

Hereinafter, the effect of the solvent supply apparatus 1 will be described in detail with reference to FIGS. 14 to 17 illustrating the operation of the solvent supply apparatus 1 according to respective processes. Also, in FIGS. 14 to 17, the portion where the processing chamber 2 is connected to the exhaust passage 71 is simply illustrated without illustrating the conveyance mechanism 12, the gas supply port 37a, and the exhaust port 71a. First, the wafer W is delivered to the moving plate 14 at the stand-by position by the external conveying arm (not illustrated). Here, the aspect of the wafer W is illustrated in FIG. 19. As illustrated, the surface of a resist pattern 74 of the wafer W is considerably rough and is formed with irregularities. Also, in the inside of the processing chamber 2, a processing gas atmosphere is substituted with a purge gas atmosphere after a processing of a previous wafer W is completed. Thus, the inside of the gas flow paths 51 of the gas supply unit 5 is placed in a state where the purge gas remains. The atmosphere within the processing area 200 contains the purge gas and atmospheric air that is introduced during the carrying-out of the previous wafer W.

Then, as illustrated in FIG. 14, the cover 31 is moved up to the carrying-in/out position and the moving plate 14 is moved to a position above the disposition unit 23. Next, when the pins 26 receive the wafer W by moving up, the moving plate 14 returns back to the stand-by position, and the pins 26 move down to dispose the wafer W on the disposition unit 23. Subsequently, as illustrated in FIG. 15, the cover 31 is moved down to the processing position to form the processing area 200. Also, the cover 31 is heated up to a temperature higher than the dew point of the solvent (e.g. 100° C.) by the heater 38 so that the solvent gas is hardly condensed. Then, the wafer W is subjected to a temperature control by the heater 24 so that the solvent gas that constitutes the processing gas may be easily attached on the surface of the resist pattern 74 during the supply of the processing gas.

Then, as illustrated in FIG. 16, the processing gas is supplied into the processing area 200 to perform a smoothing process. The processing gas refers to a gas that contains the NMP gas as the solvent gas, and the carrier gas. In the smoothing process, the wafer W is heated up to, for example, 80° C. by the heater 24, and the processing gas is supplied to the gas supply hole 52 of the gas supply unit 5 via the supply passage 41 and the gas supply path 37. Meanwhile, the exhaust unit 72 is operated to evacuate the inside of the processing area 200, and the purge gas is supplied to the purge gas flow paths 28 and 36. Here, the smoothing process is performed under atmospheric pressure while controlling the supply flow rate of the processing gas and the exhaust rate by the exhaust unit so that the supply flow rate of the processing gas to be supplied to the processing area 200 is smaller than the exhaust rate in the exhaust passage 35. For example, the supply flow rate of a gas may be 5L/min.

When the heating temperature of the wafer W is not higher than the dew point, e.g., 23° C., the solvent may be excessively condensed on the wafer, thereby causing the smoothing to locally or suddenly progress. In order to avoid this phenomenon, the wafer W is heated up to a temperature not lower than the dew point of the solvent, e.g. 80° C. by the heater 24. However, the present disclosure is not limited to the heating of the wafer W up to a temperature not lower than the dew point. The temperature of the wafer W may be set to a temperature not higher than the dew point, and, for example, the concentration and the flow rate of the solvent gas may be reduced so as to suppress the smoothing from progressing locally and suddenly.

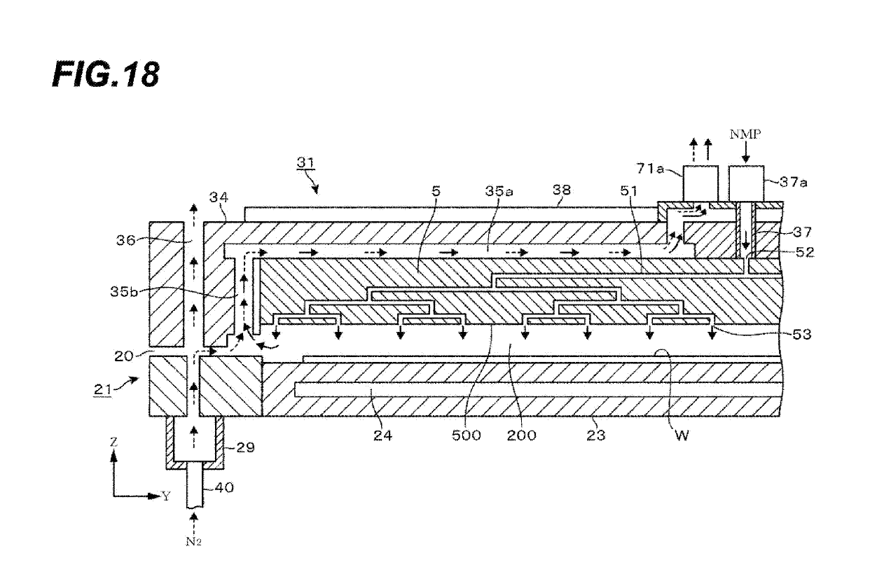

Here, FIG. 18 illustrates the flows of the processing gas and the purge gas within the processing chamber 2, in which during a processing of the wafer, the flow of the processing gas within the processing chamber 2 is indicated by solid-line arrows, and the flow of the purge gas is indicated by dotted-line arrows. In the gas supply unit 5, the processing gas supplied from the gas supply hole 52 flows to the downstream side by diffusing within the gas flow paths 51 diverged in a stepwise shape as described above. Since the purge gas remains within the gas flow paths 51, the purge gas is ejected first and then the processing gas is ejected from the gas ejecting holes 53. Here, since the gas flow paths 51 are configured to match the periods of time for gas flowing from the gas supply hole 52 to the respective gas ejecting holes 53, the periods of time until the processing gas is substituted for the atmosphere (the purge gas) within the flow paths from the gas supply hole 52 to the respective gas ejecting holes 53 are matched each other. Since the gas within the gas flow paths 51 is ejected from the respective gas ejecting holes 53 in a state where the ejecting timings and rates are matched, the purge gas remaining within the flow paths is forced out by the processing gas from the respective gas ejecting holes 53 at the matched timings In this manner, the timing when the processing gas reaches the respective gas ejecting holes 53 immediately after initiating the ejection of the processing gas is matched.

Also, in the gas ejecting surface 50, the gas ejecting holes 53, as described above, are formed in parallel to each other vertically and horizontally at equal intervals over the entire area that is larger than the area facing the to-be-processed area of the wafer W. Thus, the timings when the processing gas reaches over the entire surface of the wafer W are matched. Accordingly, since the amounts of the processing gas to be supplied to the surface of the wafer W are matched, the uniformity of the concentrations of the processing gas on the surface of the wafer W is enhanced. Thus, in the resist pattern formed on the wafer W, the supply amounts of the solvent gas are matched on the surface of the wafer W. When solvent molecules collide with the resist pattern, an outer layer portion 75 of the resist pattern 74 is swelled by absorbing the solvent, and the resist film in the portion is softened and dissolved as illustrated in FIG. 19. Thus, the resist polymer flows. Therefore, only the fine irregularities on the pattern mask surface are planarized, thereby improving the roughness of the surface of the resist pattern 74.

Meanwhile, the processing gas supplied into the processing area 200 is exhausted by the exhaust passage 35 via the exhaust holes 35b which are formed to surround the wafer W at the lateral side of the wafer W, and then recovered. Also, the exhaust rate within the exhaust passage 35 is controlled to be larger than the supply flow rate of the processing gas so as to allow the processing gas to be certainly introduced into the exhaust passage 35, and to suppress the leakage of the processing gas to the outside of the processing chamber 2. Also, the inside of the processing area 200 is in a negative pressure due to a difference between the supply flow rate of the processing gas and the exhaust rate. Thus, a part of the purge gas is drawn into the processing area 200, and is gradually exhausted, together with the processing gas, via the exhaust passage 35. Thus, there exists an air curtain of the purge gas. This also suppresses the leakage of the processing gas to the outside of the processing chamber 2.

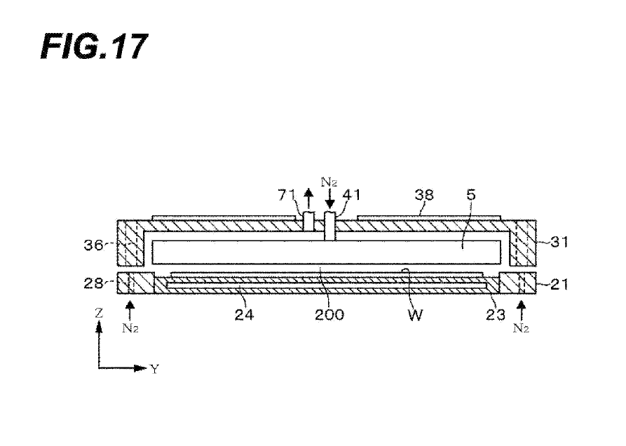

Subsequently, as illustrated in FIG. 17, the supply of the processing gas is stopped and the supply of the purge gas is initiated by switching the three-way valve 44. Then, after the inside of the processing area 200 is substituted by the purge gas, the supply of the purge gas is stopped and the exhausting of the inside of the processing area 200 is stopped. The cover 31 is moved up to the carrying-in/out position, and the wafer W is delivered to the conveyance mechanism 12 by the co-operation of the pins 26 and the conveyance mechanism 12. The wafer W is carried out to the outside of the solvent supply apparatus 1 by an external conveying arm. Meanwhile, the next wafer W is carried into the solvent supply apparatus 1, and the smoothing process is performed.

In the above described solvent supply apparatus 1 according to the present exemplary embodiment, when in the inside of the gas flow paths 51 of the gas supply unit 5, the purge gas is substituted by the processing gas at the time of processing initiation, the processing gas in which the dilution extents with the purge gas are matched on the surface of the wafer W is supplied to the entire surface of the wafer W. This is because the timing when the processing gas reaches the respective gas ejecting holes immediately after initiating the ejection of the processing gas is matched, as described above. Thus, at the time of initiating the ejection of the processing gas from the gas supply unit while the gas flow paths 51 of the gas supply unit 5 are substituted with the processing gas, the variation in concentration distribution of the solvent gas on the surface of the wafer W is suppressed. In this manner, the surface of the wafer W is placed in a state where the concentration of the solvent gas is matched until the inside of the processing area 200 is filled with the processing gas after initiating of the supply of the processing gas to the gas supply hole 52. Thus, it is possible to perform the processing with a high in-plane uniformity. When the processing is the smoothing process, the roughness of the surface of the resist pattern may be improved with a high uniformity on the surface of the wafer W.

Meanwhile, when the processing gas atmosphere within the processing area 200 is substituted with a purge gas atmosphere, the processing gas is gradually diluted with the purge gas within the processing area 200. At this time, the period of time until the atmosphere (the processing gas) within the flow paths from the gas supply hole 52 to the respective gas ejecting holes 53 is substituted by the purge gas is matched. Thus, the timing when the purge gas reaches the respective gas ejecting holes 53 immediately after initiating of the ejection of the purge gas is matched. This makes the dilution extents of the processing gas uniform with the purge gas on the entire surface of the wafer W. Accordingly, even during the substitution of the purge gas for the inside of the processing area 200, the concentrations of the processing gas on the surface of the wafer W may become uniform.

Also, in the gas supply unit 5, since the volume of the space through which a gas flows is very small, the period of time when the gas passes through the inside of the gas supply unit 5 is shortened, and the supply of the gas into the processing area 200 may be quickly performed. Thus, the smoothing process may be quickly initiated, and also the substitution with the purge gas may be performed within a short time. Also, the gas flow paths 51 are configured to be diverged in a stepwise diagram shape that determines a tournament combination. Accordingly, in the gas ejecting holes 53 opened at the first area, the respective flow path lengths and the respective flow path diameters may be easily matched each other, allowing the design to be easily performed.

Also, the present disclosure is suitable for a substrate with a large size (large area) not smaller than a 200 mm wafer, and is more suitable for a substrate with a large size not smaller than a 300 mm wafer.

Also, the gas flow paths 51 are configured by laminating the plurality of plates 67 which have the groove portions 670 or the through holes 671 formed on the surfaces thereof. Thus, the above gas flow paths 51 in the complicated shape may be manufactured with a good dimensional accuracy. Also, since the warming heater 47 and the heater 38 are provided in the supply passage 41 of the solvent and the cover 31 of the processing chamber 2, respectively, the solvent gas is suppressed from being condensed in the flow paths of the solvent gas when the solvent gas is supplied into the processing area 200 or is exhausted from the processing area 200. When the solvent gas is condensed within the flow paths of the solvent gas, the concentration of the solvent gas in the processing gas to be supplied to the wafer W may be varied, or a solvent liquid is moved in concurrence with the through-flowing of the processing gas, and dropped on the wafer W, thereby lowering the in-plane uniformity in the smoothing process.

### Second Exemplary Embodiment

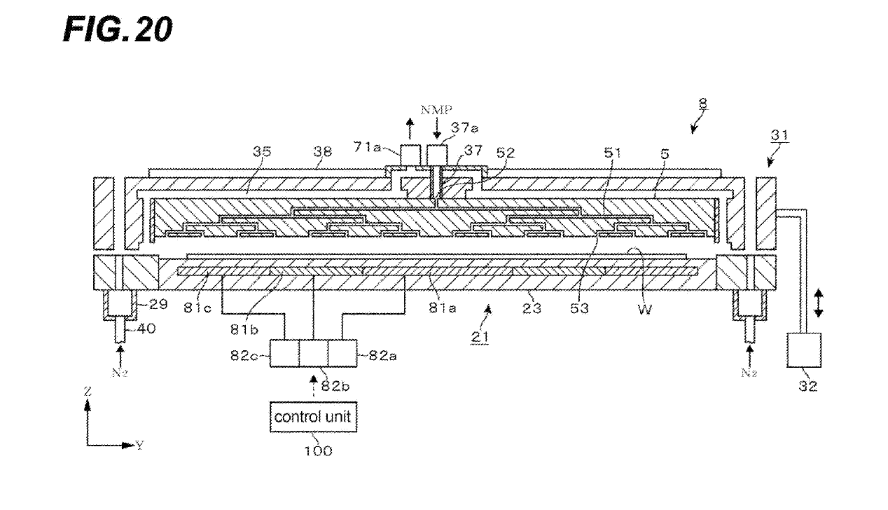

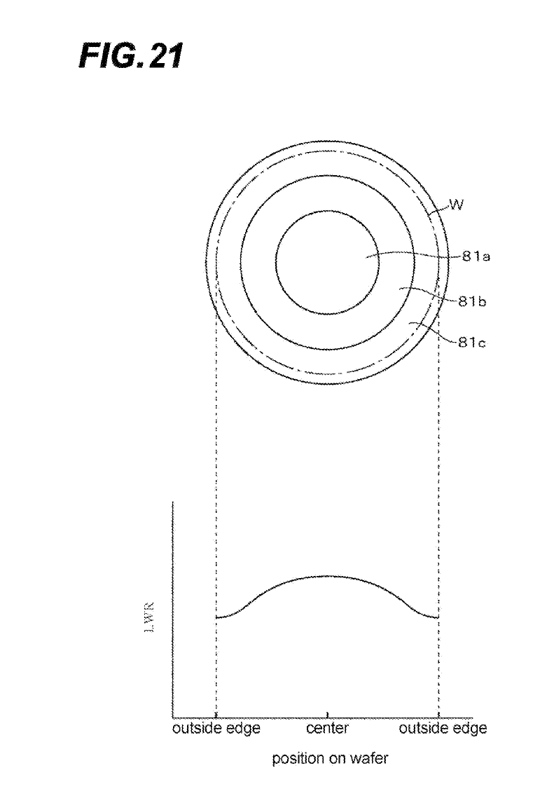

FIG. 20 illustrates a solvent supply apparatus 8 according to a second exemplary embodiment. In the solvent supply apparatus 8, elements which are configured in the same manner as those in the solvent supply apparatus 1 are given the same reference numerals and the descriptions thereof will be omitted. The solvent supply apparatus 8 is different from the solvent supply apparatus 1 in that a plurality of heating mechanisms are provided in the disposition unit 23, which are configured to be individually subjected to temperature control. For example, a heater 81 that constitutes the heating mechanism is configured to control the temperature in the diametrical direction of the wafer W disposed on the disposition unit 23. Specifically, the heater 81 according to the present exemplary embodiment is, as illustrated in FIGS. 20 and 21, provided with a first heater 81a configured to heat the central portion of the wafer W on the disposition unit 23, and second and third annular heaters 81b and 81c which are formed concentrically with the first heater 81a around the first heater 81a. The first to third heaters 81a to 81c are connected to power supply units 82a to 82c, respectively, and are configured to be individually supplied with power based on the command from the control unit 100.

In such a configuration, since the first to third heaters 81a to 81c individually heat the wafer W, it is possible to control the adsorption amount of the solvent gas in each zone. That is, when the temperature of the wafer is high, the solvent adsorbed on the wafer may be easily evaporated, thereby reducing the amount of the solvent adsorbed on the wafer surface. Meanwhile, when the temperature of the wafer is low, a period of time when the solvent adsorbed on the wafer stays is prolonged, thereby increasing the amount of the solvent adsorbed on the wafer surface. In this manner, since the adsorption amount of the solvent is adjusted by controlling the temperature of the wafer surface in each zone, it is possible to control the extent of progress in a smoothing process in each zone.

Specifically, for example, a test wafer is subjected to a smoothing process, and its LWR is measured. Based on the measurement result, the temperature of the heater 81 at the time of performing a smoothing process on a product wafer is controlled. For example, since the processing gas ejected from the gas ejecting holes 53 at matched timings flows toward the exhaust holes 35b provided at the lateral side of the wafer W, the resist pattern may be further dissolved at the circumferential edge area of the wafer W than at the central area. In this case, as illustrated in FIG. 21, for example, the LWR value at the circumferential edge area of the wafer W is lower than the LWR value at the central area. That is, the surface roughness of the pattern mask is improved at the circumferential edge area of the wafer W, while fine irregularities still remain on the surface of the pattern mask at the central area of the wafer W.

When the smoothing may be more easily performed at the circumferential edge area than at the central area, as described above, the setting temperatures of the first to third heaters 81a to 81c are controlled so that the temperature at the central area of the wafer W may be lower than that at the circumferential edge area at the time of supplying the processing gas into the processing area 200. Accordingly, when the processing is performed, the adsorption amount of the solvent gas at the central area of the wafer W is increased, and thus the extents of progress in smoothing on the wafer surface are matched. For example, according to the kind or supply amount of the solvent, or the exhaust rate of the processing area 200, the smoothing may be more easily performed at the central area of the wafer W than at the circumferential edge area. In this case, the setting temperatures of the first to third heaters 81a to 81c are controlled so that the temperature at the circumferential edge area of the wafer W may be lower than that at the central area. Accordingly, the adsorption amount of the solvent gas at the circumferential edge area is increased to perform the smoothing process.

In the present exemplary embodiment, since the plurality of first to third heaters 81a to 81c independently from each other heat the wafer W, the adsorption amount of the solvent gas on the wafer surface may be controlled in each of zones provided with the first to third heaters 81a to 81c. Thus, when there occurs a requirement for controlling the extent of progress in the smoothing process on the wafer surface according to, for example, the kind or supply flow rate of the resist or the solvent, the exhaust rate, and the variation of the resist pattern, a countermeasure may be easily performed. As a result, the roughness on the surface of the resist pattern may be improved in a state where the high in-plane uniformity is secured. Also, when the solvent coating apparatus of the present disclosure or a LWR test device configured to inspect a smoothing result is incorporated in a coating/developing device provided with a coating unit configured to perform coating of the resist, or a developing unit configured to perform developing processing, a countermeasure may be quickly performed based on the test result. Accordingly, when there occurs a requirement for controlling the extent of progress in the smoothing process on the wafer surface, the setting of optimized process conditions may be quickly performed.

Subsequently, an example of controlling the temperature of the wafer in the smoothing process will be described.

### Temperature Control Example 1

In the smoothing process, until a predetermined time is elapsed after initiating the supply of the processing gas into the processing area 200, the wafer W is heated up to a temperature not lower than a dew point of the solvent gas (e.g. 100° C.) by the heater 24 or 81. Then, after the predetermined time is elapsed after initiating the supply of the processing gas into the processing area 200, a temperature control is performed to cool the wafer W to, for example, 80° C. In this case, as described above, the progress in smoothing is suppressed at the initial stage of solvent supply since the wafer W is heated up to the temperature not lower than the dew point. Meanwhile, after the predetermined time is elapsed after initiating the supply of a solvent, the smoothing is quickly progressed due to the decrease of the temperature of the wafer W.

Immediately after the supply of the processing gas into the processing area 200 is initiated, the purge gas or the atmospheric air exists within the processing area 200 as described above. Thus, the concentration of the processing gas is low. Then, when the processing gas is continuously supplied into the processing area 200, the concentration of the processing gas is gradually increased. Accordingly, for some time after initiating the supply of the processing gas into the processing area 200, the concentration of the processing gas within the processing area 200 is hardly stabilized.

As described above, the concentration of the processing gas is hardly stabilized at the initial stage of supply of the processing gas. However, in the present disclosure, since the concentrations of a ejected gas are matched in the gas ejecting holes 53 as described above, the uniformity of the smoothing process on the surface of the wafer W is enhanced. However, briefly speaking, a technique of grasping, for example, the timing when the inside of the processing area 200 is substituted with the processing gas, and performing a series of processes so as to progress the smoothing process at the timing is also effective. That is, in the present disclosure, a technique of controlling the temperature of the wafer W at the initial stage of supply of the processing gas to be higher than that of the wafer W after stabilization of supply of the processing gas is effective. In this manner, the smoothing process may be performed in a state where the entire surface of the wafer is in contact with the processing gas at the stabilized concentration. Thus, it is expected to further improve the in-plane uniformity in the smoothing process.

### Temperature Control Example 2

In the smoothing process, the temperature of the wafer W at the time of stopping the smoothing reaction is controlled to be higher than that at the time of performing the smoothing process. When the solvent is adsorbed on the resist pattern, the flowability of the resist is increased until the surface is dissolved. Then, the planarization of roughness of the surface is rapidly progressed. Thus, when the smoothing is progressed as it stands, dissolution of the resist is excessively progressed, thereby collapsing the pattern shape. Accordingly, it is desirable to stop the smoothing process at the timing when the roughness of the surface of the resist pattern is improved. For example, after the timing when the resist pattern is dissolved is grasped, the wafer W may be heated at a temperature higher by 20° C. than the temperature for performing the smoothing process, for example, at a timing that is 2 to 10 seconds ahead of the grasped timing. In this manner, when the heating temperature of the wafer W is increased at the above described timing, the solvent gas is hardly attached on the wafer W, and the solvent is easily evaporated. As a result, the smoothing process is stopped, and thus the dissolution of the resist pattern may be stopped at the timing when the roughness of the surface of the resist pattern is improved.

In this case, the temperature control of the wafer W may be performed by the heater 24 or 81, or a purge gas at a high temperature (e.g. 100° C.) may be supplied into the processing area 200 so as to increase the temperature of the wafer W. In a configuration where the high temperature purge gas is supplied to the processing area 200, until the processing area 200 is completely substituted with the purge gas, the processing gas exists within the processing area 200 and thus the smoothing process is in progress. Accordingly, when at the above described timing, the supply of the processing gas is stopped, and the high temperature purge gas is supplied, the smoothing process may be stopped, and the atmosphere within the processing area 200 may be substituted with the purge gas.

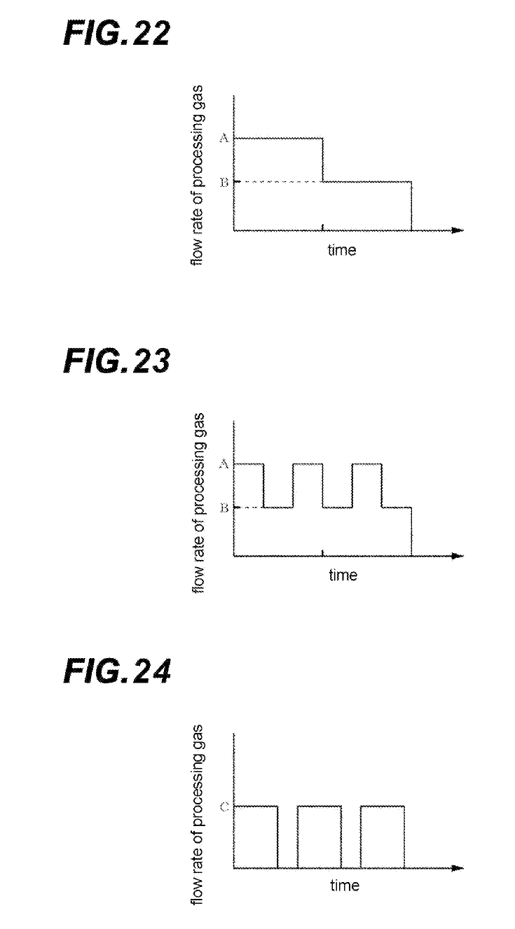

Also, in the solvent supply apparatus 1 or 8 according to the present disclosure, as illustrated in FIGS. 22 to 24, the supply amount of the processing gas may be controlled. In the example illustrated in FIG. 22, the supply amount is changed during the smoothing process. The example is a control example in which, for example, the processing gas is supplied at A L/min in the first half of a processing step, and supplied at B L/min in the latter half. Also, the example illustrated in FIG. 23 is a control example in which a step of supplying the processing gas at A L/min and a step of supplying the processing gas at B L/min are alternately repeated. The example illustrated in FIG. 24 is a control example in which a step of supplying the processing gas at C L/min is repeatedly performed intermittently.

As described above, in the smoothing, there is a timing when planarization of the roughness of the surface is rapidly progressed. Thus, when the smoothing reaction is excessively quickly progressed, it is difficult to determine the time of stopping the smoothing reaction. When the supply flow rate of the processing gas is controlled in this manner, a period of time when the smoothing is highly progressed and a period of time when the smoothing is slightly progressed may exist among smoothing processes. Thus, it is easy to determine the time of stopping the smoothing reaction, and the smoothing reaction may be stopped at the optimized timing. Accordingly, it is possible to improve the roughness of the surface of the resist pattern with a high in-plane uniformity.

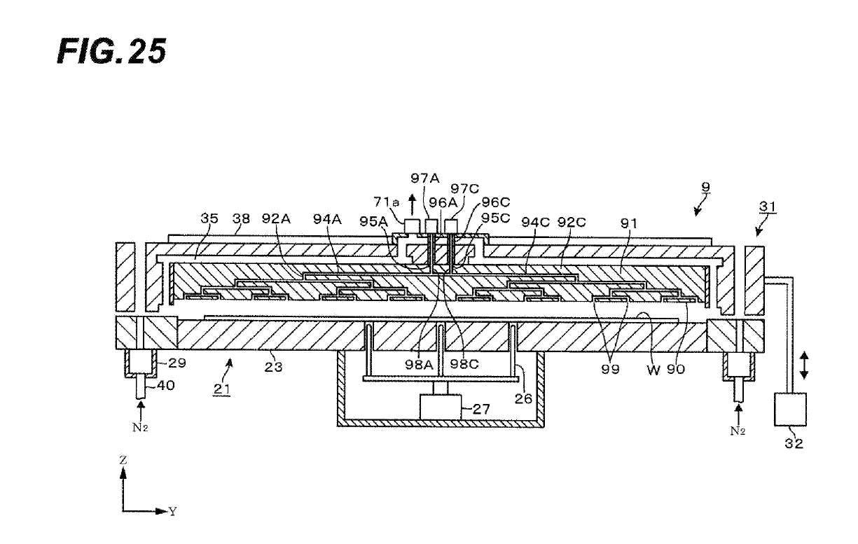

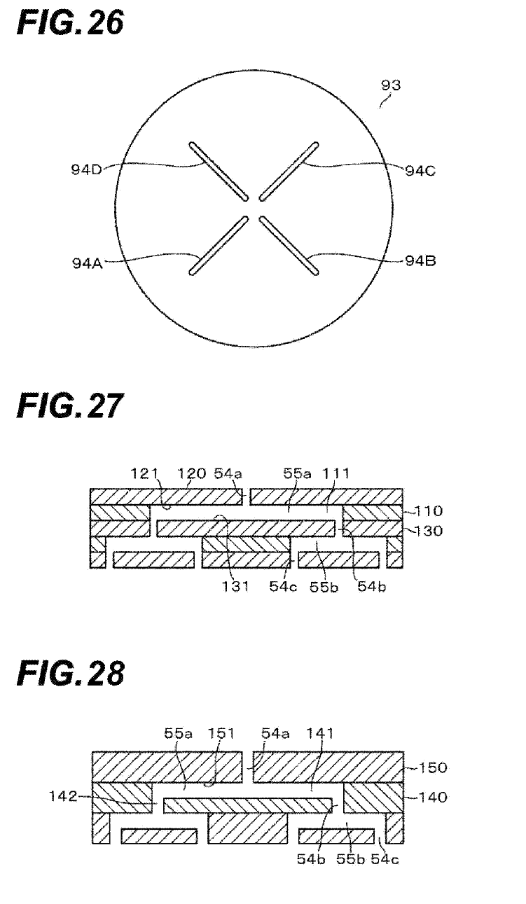

The above described gas supply unit may be provided with a plurality of gas flow paths. FIG. 25 illustrates a further exemplary embodiment where a gas supply unit 91 of a solvent supply apparatus 9 is provided with four gas flow paths 92A, 92B, 92C, and 92D (92B, and 92D are not illustrated). The gas flow paths 92A to 92D are configured in which four horizontal flow paths 94A to 94D of first flow paths 93 as illustrated in FIG. 26 are connected to vertical flow paths 98A to 98D, respectively, and upstream ends of the vertical flow paths 98A to 98D form gas ejecting holes 95A to 95D, respectively. The gas ejecting holes 95A to 95D are connected to the supply passage 41 of the solvent gas via gas supply paths 96A to 96D, and gas supply ports 97A to 97D, respectively. Reference numerals 95B, 95D, 96B, 96D, 97B, 97D, 98B, and 98D are not illustrated in the drawing. The downstream sides of the first flow paths 93 are configured in the same manner as those of the gas flow paths 51. Accordingly, in the present exemplary embodiment, a group of the first flow paths 93 which include the vertical flow paths 98A to 98D and the horizontal flow paths 94A to 94D are provided. The vertical flow paths 98A to 98D have upper ends communicated with the gas ejecting holes 95A to 95D, and the horizontal flow paths 94A to 94D horizontally extend radially from the lower end sides of the vertical flow paths 98A to 98D.

In a gas ejecting surface 90 of the gas supply unit 91, gas ejecting holes 99 are also provided to be opened over the entire surface of an area that is larger than the area facing the effective area of the wafer W. Also, the flow path lengths and the flow path diameters of the diverged gas flow paths 92 are set so that the periods of time for gas flowing from the gas supply holes 95A to 95D to the respective gas ejecting holes 99 may be matched each other. Other configurations are the same as those in the above described solvent supply apparatus 1 illustrated FIG. 1. The disposition unit 23 of the solvent supply apparatus 9 may be provided with the heater 81 illustrated in FIG. 20.

In the above, the above described gas supply unit 5 or 91 may be configured so that the gas ejecting surface 50 or 90 may be positioned within the processing area 200, or configured so that a part of the gas ejecting surface 50 or 90 may be exposed to the outside of the processing chamber 2. Also, the gas supply unit 5 or 91 may be configured as illustrated in FIGS. 27 to 29. FIGS. 27 to 29 schematically illustrate the first flow paths 61 and the second flow paths 62 of the gas supply unit 5. In an example illustrated in FIG. 27, the horizontal flow paths 55 are formed by one plate 110 that has slits 111 formed on the surface thereof, a plate surface 121 of another plate 120 piled up at the upper side of the plate 110, a plate surface 131 of the other plate 130 piled up at the lower side of the plate 110, and the slits 111.

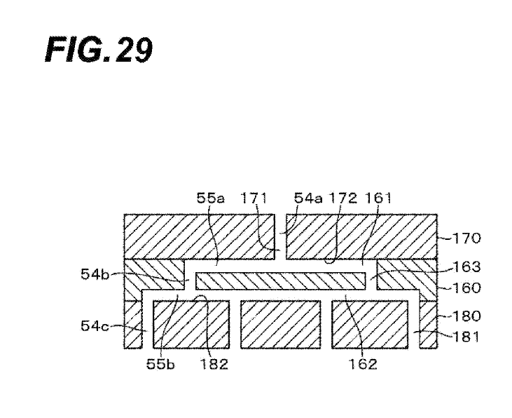

Also, FIG. 28 illustrates another example, in which groove portions 141 and through holes 142 for the vertical flow paths 54 are formed in the surface of one plate 140, and the horizontal flow paths 55 are formed by the plate 140, a plate surface 151 of another plate 150 piled up at the upper side of the plate 140, and the groove portions 141. Also, in FIG. 29, groove portions 161 and 162 are formed, respectively, in front and rear surfaces of a plate 160, and through holes 163 which are connected to the groove portions 161 and 162 and form the vertical flow paths 54 are formed. Also, through holes 171 and 181 which form the vertical flow paths 54 are formed, respectively, in plates 170 and 180 piled up on the plate 160. The horizontal flow paths 55a and 55b are formed, respectively, by plate surfaces 172 and 182 of the plates 170 and 180 piled up on the plate 160, and the groove portions 161 and 162 of the plate 160. Also, the horizontal flow paths may be formed by one plate that has groove portions or slits formed on the rear surface thereof, a plate surface of another plate piled up at the lower side of the plate, and the groove portions or the slits. The depth of the horizontal flow paths 55 formed in this manner may be set in a range from 0.3 mm to 0.9 mm.

Also, it is not necessary to supply the purge gas for substitution to the processing area 200 from the gas supply unit 5 or 91. In this case, when the inside of the processing area 200 is substituted with the purge gas, the supply of the processing gas to the processing area 200 may be stopped, and the inside of the processing area 200 may be exhausted by the exhaust unit 72, thereby removing the processing gas within the processing area 200 and the processing gas within the gas flow paths 51 or 92 of the gas supply unit 5 or 91. Then, the purge gas is supplied into the processing area 200 without being passed through the gas supply unit 5 or 91. Accordingly, the purge gas fills the inside of the processing area 200 and the gas flow paths 51 or 92, thereby substituting the processing area 200 and the gas flow paths 51 or 92.

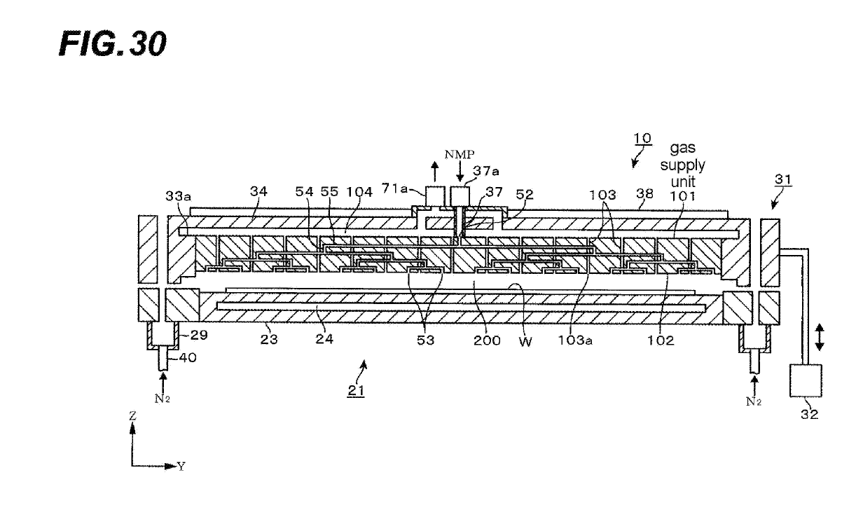

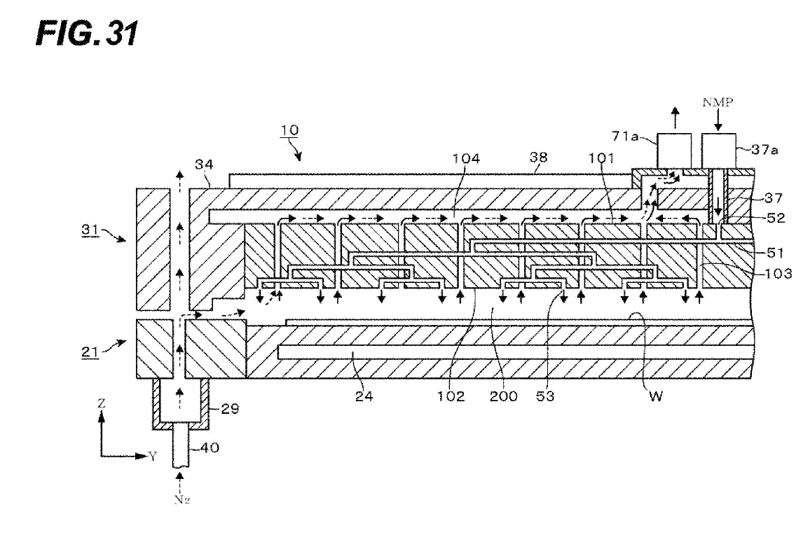

In the above, the gas supply unit of the present disclosure may be configured as illustrated in FIGS. 30 and 31. In the present exemplary embodiment, a gas supply unit 101 includes exhaust holes 103 which have one end sides (lower end sides) opened at a gas ejecting surface 102. The exhaust holes 103 may be formed to extend in a direction perpendicular to the wafer W disposed on the disposition unit 23, and penetrate the gas supply unit 101. Also, the other end sides (upper end sides) of the exhaust holes 103 are configured to communicate with an exhaust space 104 formed between the upper wall portion 34 of the cover 31 and the top surface of the gas supply unit 101. In the gas supply unit 101, the exhaust holes 103 are formed so that they may not interfere with the gas flow paths 51, and openings 103a at the one end sides may be distributed at predetermined intervals in the gas ejecting surface 102. The exhaust space 104 forms an exhaust passage, and is connected to the exhaust port 71a. The gas flow paths 51 or other elements are configured in the same manner as those in the above described solvent supply apparatus 1 illustrated in FIG. 1 except that the exhaust holes 35b are not formed in the protrusion 33a of the cover 31. When the gas supply unit 101 is formed, a plate on which groove portions or slits are formed, a plate in which thorough holes for forming vertical flow paths are formed, and a plate in which through holes for forming the exhaust holes 103 are formed are prepared. The plurality of plates are configured to form the horizontal flow paths 55, the vertical flow paths 54, and the exhaust holes 103 by being laminated and bonded to each other. Also, the gas supply unit 101 may be provided in the above described solvent supply apparatus 8 or 9 illustrated in FIG. 20 or 25.

The flow of a gas in the solvent supply apparatus 10 provided with the gas supply unit 101 is illustrated in FIG. 31.

In FIG. 31, the solid-line arrows indicate the processing gas, and the dotted-line arrows indicate the purge gas, respectively. In the gas supply unit 101, the processing gas supplied from the gas supply hole 52 flows through inside of the gas flow paths 51, ejected from the gas ejecting holes 53 of the gas ejecting surface 102, diffused within the processing area 200, and supplied to the wafer W on the disposition unit 23. The atmosphere within the processing area 200 is gradually exhausted toward the exhaust space 104 via the exhaust holes 103 opened at the gas ejecting surface 102. In this manner, in the gas supply unit 101, supply and exhausting of a gas are performed through the gas ejecting surface 102. Accordingly, the occurrence of an air flow toward the circumferential edge area from the central area of the wafer W is suppressed as the gas is exhausted through the exhaust holes 35b in the solvent supply apparatus 1. Thus, there is no concern that the gas concentration at the circumferential edge side of the wafer W becomes higher than that at the central side of the wafer W on the wafer surface, and thus the uniformity of a gas concentration on the wafer surface is further enhanced.

Also, the present disclosure may be employed in a substrate processing apparatus configured to perform a processing of a substrate by supplying a processing gas under atmospheric pressure, such as, for example, an atmospheric CVD apparatus, and an atmospheric etching apparatus, or in a hydrophobic treatment (ADH treatment) of a substrate surface by a hydrophobic gas. Also, the atmospheric pressure in the present disclosure includes a state of a reduced pressure slightly lower than an atmospheric pressure.

### Evaluation Test

Subsequently, an evaluation test that was performed in relation to the present disclosure will be described. In a plurality of positions along the diametrical direction in a wafer W (referred to as wafer A1) formed with a resist pattern, an LWR (difference between maximum width and minimum width of the pattern) of the resist pattern was measured. Also, a wafer A2 that was formed with a resist pattern in the same manner as in the wafer A1 was prepared. The wafer A2 was processed according to the first exemplary embodiment, and an LWR of the resist pattern was measured in the same manner as in the wafer A1.

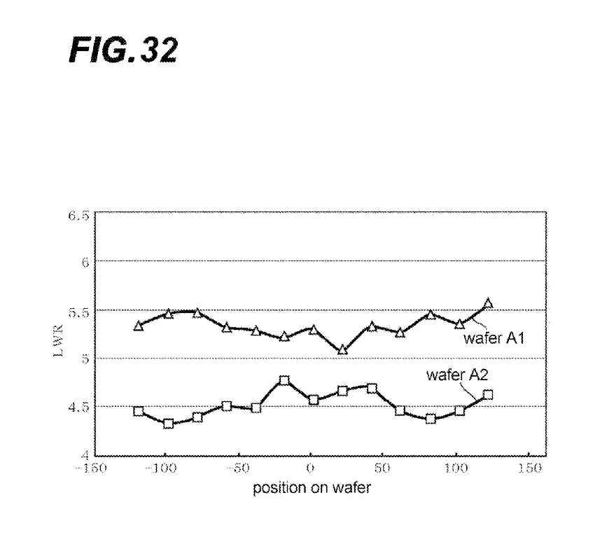

In the graph in FIG. 32, the evaluation test results are indicated by ^{Δ} in the wafer A1, and □ in the wafer A2, respectively. The horizontal axis indicates measurement positions at the wafer W, in which in the horizontal axis, −150, and +150 indicate one end and the other end, respectively, on a line according to the diameter of the wafer W, and 0 indicates the center of the wafer W. The vertical axis indicates an LWR, and the unit is nm. As illustrated in the graph, the wafer A2 shows a lower LWR than the wafer A1 at each of the measurement positions. From the evaluation test results, it was found that the technique of the present disclosure is effective in improvement of roughness of a resist pattern.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus configured to perform processing on a substrate by a processing gas under an atmospheric pressure within a processing chamber, the substrate processing apparatus comprising:
a disposition unit provided within the processing chamber configured to dispose the substrate; and
a gas supply unit equipped with a gas ejecting surface facing the substrate and provided to supply the processing gas to the substrate disposed on the disposition unit,
wherein the gas supply unit includes a plurality of gas ejecting holes formed to be distributed over an entire surface of an area of the gas ejecting surface facing the substrate, and gas flow paths having an upstream side communicated with a common gas supply hole and diverged on the way to have a downstream side opened as the plurality of gas ejecting holes, and
a flow path length and a flow path diameter of the diverged gas flow path are set such that periods of time for gas flowing from the gas supply hole to the plurality of gas ejecting holes match each other.

2. The substrate processing apparatus of claim 1, wherein the gas flow path formed to be diverged in a stepwise diagram shape that determines a tournament combination from the gas supply hole to the gas ejecting holes.

3. The substrate processing apparatus of claim 1, wherein when a direction perpendicular to the substrate is defined as a vertical direction, the gas flow paths include:
a group of first flow paths which have a vertical flow path and a plurality of horizontal flow paths, the vertical flow path extending vertically and having an upper end side communicated with the gas supply hole, and the plurality of horizontal flow paths extending horizontally radially from a lower end side of the vertical flow path, and
a group of second flow paths which have a plurality of vertical flow paths extending downwardly from downstream ends of the horizontal flow paths, respectively, in the group of the first flow paths, and a plurality of horizontal flow paths extending radially and horizontally from lower end sides of the vertical flow paths.

4. The substrate processing apparatus of claim 3, wherein the gas supply unit includes a plurality of plates which are vertically laminated with each other,
the plurality of plates include a plate formed with groove portions or slits, and a plate in which through holes forming the vertical flow paths are formed, and
the groove portions or the slits formed on one plate together with a plate surface of another plate to be piled up on the plate form the horizontal flow paths.

5. The substrate processing apparatus of claim 4, wherein the plurality of gas ejecting holes include a plurality of gas ejecting holes included in a first area as a projection area of a region close to a center of the substrate, and a plurality of gas ejecting holes included in a second area as a projection area of a region close to an outer periphery of the substrate other than the region close to the center of the substrate, and
in the plurality of gas ejecting holes included in the first area, flow path lengths of the gas flow paths are matched from the gas supply hole to the gas ejecting holes, respectively.

6. The substrate processing apparatus of claim 1, wherein the processing performed on the substrate by supplying the processing gas is processing performed to improve the roughness of the pattern mask by supplying a solvent gas for dissolving a resist film on the substrate that has a pattern mask formed through exposure and development processing.

7. A substrate processing apparatus configured to perform processing on a substrate by a processing gas under an atmospheric pressure within a processing chamber, the substrate processing apparatus comprising:
a disposition unit provided within the processing chamber configured to dispose the substrate; and
a gas supply unit equipped with a gas ejecting surface facing the substrate and provided to supply the processing gas to the substrate disposed on the disposition unit,
wherein the gas supply unit includes: a plurality of gas ejecting holes formed to be distributed over an entire surface of an area of the gas ejecting surface facing the substrate, and gas flow paths configured by using a plurality of plates which are vertically laminated with each other having an upstream side communicated with a common gas supply hole, and diverged on the way to have a downstream side opened as the plurality of gas ejecting holes,
wherein, when a direction perpendicular to the substrate is defined as a vertical direction, the gas flow path includes: a group of first flow paths which have a vertical flow path and a plurality of horizontal flow paths, the vertical flow path extending vertically and having an upper end side communicated with the gas supply hole and the plurality of horizontal flow paths extending horizontally radially from a lower end side of the vertical flow path, and a group of second flow paths which have a plurality of vertical flow paths extending downwardly from downstream ends of the horizontal flow paths, respectively, in the group of the first flow paths and a plurality of horizontal flow paths extending radially and horizontally from lower end sides of the vertical flow paths,
wherein the plurality of plates include a plate formed with groove portions or slits and a plate in which through holes forming the vertical flow paths are formed, and
wherein the groove portions or the slits formed on one plate together with a plate surface of another plate to be piled up on the plate form the horizontal flow paths, and flow path lengths of the gas flow paths are matched from the gas supply hole to the gas ejecting holes, respectively.

8. The substrate processing apparatus of claim 7, wherein the plurality of gas ejecting holes include a plurality of gas ejecting holes included in a first area as a projection area of a region close to a center of the substrate, and a plurality of gas ejecting holes included in a second area as a projection area of a region close to an outer periphery of the substrate other than the region close to the center of the substrate, and
horizontal flow paths included in the second area in gas flow paths extending from the gas supply hole to the plurality of gas ejecting holes included in the second area have a smaller flow path diameter than horizontal flow paths in gas flow paths extending from the gas supply hole to the plurality of gas ejecting holes included in the first area.

9. The substrate processing apparatus of claim 8, wherein the plurality of gas ejecting holes include the plurality of gas ejecting holes included in the first area as the projection area of the region close to the center of the substrate, and the plurality of gas ejecting holes included in the second area as the projection area of the region close to the outer periphery of the substrate other than the region close to the center of the substrate, and
vertical flow paths included in the second area in the gas flow paths extending from the gas supply hole to the plurality of gas ejecting holes included in the second area have a smaller flow path diameter than vertical flow paths in the gas flow paths extending from the gas supply hole to the plurality of gas ejecting holes included in the first area.

10. The substrate processing apparatus of claim 7, wherein the plurality of gas ejecting holes include a plurality of gas ejecting holes included in a first area as a projection area of a region close to a center of the substrate, and a plurality of gas ejecting holes included in a second area as a projection area of a region close to an outer periphery of the substrate other than the region close to the center of the substrate, and
vertical flow paths included in the second area in gas flow paths extending from the gas supply hole to the plurality of gas ejecting holes included in the second area have a smaller flow path diameter than vertical flow paths in gas flow paths extending from the gas supply hole to the plurality of gas ejecting holes included in the first area.

11. The substrate processing apparatus of claim 1, wherein the processing performed on the substrate by supplying the processing gas is processing where a solvent gas for dissolving a resist film is supplied on the substrate that has a pattern mask formed through exposure and development processing, so as to improve roughness of the pattern mask.

12. A gas supply apparatus configured to supply a processing gas to a substrate disposed within a processing chamber set to an atmospheric pressure, the gas supply apparatus comprising:
a gas ejecting surface facing the substrate disposed within the processing chamber;
a plurality of gas ejecting holes formed to be distributed on the gas ejecting surface; and
gas flow paths which have an upstream side communicated with a common gas supply hole, and diverged on the way to have a downstream side opened as the plurality of gas ejecting holes,
wherein a flow path length and a flow path diameter of the diverged gas flow paths are set such that periods of time for gas flowing from the gas supply hole to the plurality of gas ejecting holes are matched each other.

13. A gas supply apparatus configured to supply a processing gas to a substrate disposed within a processing chamber set to an atmospheric pressure, the gas supply apparatus comprising:
a gas ejecting surface facing the substrate disposed within the processing chamber;
a plurality of gas ejecting holes formed to be distributed on the gas ejecting surface; and
gas flow paths configured by using a plurality of plates which are laminated with each other in a direction perpendicular to the substrate and having an upstream side communicated with a common gas supply hole, and diverged on the way to have a downstream side opened as the plurality of gas ejecting holes,
wherein when the direction perpendicular to the substrate is defined as a vertical direction, the gas flow paths include a group of first flow paths which have a vertical flow path and a plurality of horizontal flow paths, the vertical flow path extending vertically and having an upper end side communicated with the gas supply hole, and the plurality of horizontal flow paths extending horizontally radially from a lower end side of the vertical flow path, and a group of second flow paths which have a plurality of vertical flow paths extending downwardly from downstream ends of the horizontal flow paths, respectively, in the group of the first flow paths, and a plurality of horizontal flow paths extending radially and horizontally from lower end sides of the vertical flow paths,
wherein the plurality of plates include a plate formed with groove portions or slits, and a plate in which through holes forming the vertical flow paths are formed,
wherein the groove portions or the slits formed on one plate together with a plate surface of another plate to be piled up on the plate form the horizontal flow paths, and
flow path lengths of the gas flow paths are matched from the gas supply hole to the gas ejecting holes, respectively.
